(19) United States
(12) Patent Application Publication
(10) Pub. No.: US 2024/0390953 A1
(43) Pub. Date: Nov. 28, 2024

(54) SUBSTRATE PROCESSING APPARATUS AND SUBSTRATE PROCESSING METHOD

(71) Applicant: SCREEN HOLDINGS CO., LTD., Kyoto (JP)

(72) Inventors: Takuma TAKAHASHI, Kyoto-shi, Kyoto (JP); Ryo MURAMOTO, Kyoto-shi, Kyoto (JP); Kazuki NAKAMURA, Kyoto-shi, Kyoto (JP); Kazuki CHIBA, Kyoto-shi, Kyoto (JP)

(21) Appl. No.: 18/694,385

(22) PCT Filed: Jul. 25, 2022
(86) PCT No.: PCT/JP2022/028658

§ 371 Date: Mar. 21, 2024

(30) Foreign Application Priority Data
Sep. 22, 2021 (JP) 2021-154407

(51) Int. Cl. B08B 3/10; B08B 3/04; H01L 21/67

(52) U.S. Cl. CPC B08B 3/10; B08B 3/041; H01L 21/67259

(57) ABSTRACT

A substrate processing apparatus includes a substrate holder that holds an outer peripheral end of a substrate, a processor that processes a front surface or a back surface of the substrate, and a holding controller that controls the substrate holder such that a center portion of the substrate is displaced in an upward direction or a downward direction in a period during which the substrate is processed by the processor.

### CROSS-REFERENCE TO RELATED APPLICATIONS

The present application is a 35 U.S.C. § 371 national stage application of International Application No. PCT/JP2022/028658, filed Jul. 25, 2022, which claims priority to Japanese Patent Application No. 2021-154407, filed Sep. 22, 2021, the contents of which are incorporated herein by reference.

### TECHNICAL FIELD

The present invention relates to a substrate processing apparatus and a substrate processing method.

### BACKGROUND ART

A substrate processing apparatus is used to perform various processes on various substrates such as a substrate for an FPD (Flat Panel Display) that is used for a liquid crystal display device, an organic EL (Electroluminescence) display device or the like, a semiconductor substrate, a substrate for an optical disc, a substrate for a magnetic disc, a substrate for a magneto-optical disc, a substrate for a photomask, a ceramic substrate or a substrate for a solar cell. A substrate cleaning device is used to clean a substrate.

For example, a substrate cleaning device described in Patent Document 1 includes two suction pads for holding the back-surface peripheral portion of a wafer, a spin chuck for holding the back-surface center portion of the wafer and a brush for cleaning the back surface of the wafer. The two suction pads hold the wafer and move in a transverse direction. In this state, the back-surface center portion of the wafer is cleaned by the brush. Thereafter, the spin chuck receives the wafer from the suction pads. Further, the spin chuck rotates about an axis (rotation shaft) extending in a vertical direction while holding the back-surface center portion of the wafer. In this state, the back-surface peripheral portion of the wafer is cleaned by the brush.
[Patent Document 1] JP 5904169 B2

### SUMMARY OF INVENTION

### Technical Problem

When the peripheral portion of the wafer is held by the suction pads, the center portion of the wafer is displaced downwardly due to its own weight, and the lower surface of the wafer is curved. Further, when the brush is pressed against the back-surface center portion of the wafer from below in order to be brought into contact with the wafer, the center portion of the wafer is displaced upwardly due to a load applied by the brush, and the lower surface of the wafer is curved. Further, the wafer itself may be bent due to the influence of the previous processing step. In such a situation, in a case in which the upper surface of the brush is flat, the entire upper surface of the brush does not come into contact with the wafer, and the area in which the brush and the wafer come into contact with each other is reduced. Therefore, the frequency of cleaning of the region of the wafer that does not come into contact with the brush is reduced.

An object of the present invention is to provide a substrate processing apparatus which can efficiently process a substrate.

### Solution to Problem

(1) According to one aspect of the present invention, a substrate processing apparatus includes a substrate holder that holds an outer peripheral end of a substrate, a processor that processes a front surface or a back surface of the substrate, and a holding controller that controls the substrate holder such that a center portion of the substrate is displaced in an upward direction or a downward direction in a period during which the substrate is processed by the processor. Because the substrate holder is controlled such that the center portion of the substrate is displaced in the upward direction or the downward direction during the process for the substrate, the substrate can be displaced to have a shape suited for the process. Therefore, it is possible to provide the substrate processing apparatus that can efficiently process the substrate.

(2) The substrate holder has two pressers that are arranged to be opposite to each other with the substrate interposed between the two pressers, and the holding controller adjusts a distance between the two pressers. Therefore, because the distance between the two pressers is adjusted, the substrate can be easily deformed.

(3) The substrate holder has two grippers that are arranged to be opposite to each other with the substrate interposed between the two grippers, each of the two grippers includes an upper gripper that abuts against the front surface of the substrate and a lower gripper that abuts against the back surface of the substrate, and the holding controller adjusts a force to be applied to the front surface of the substrate by the upper gripper and a force to be applied to the back surface of the substrate by the lower gripper.

(4) The processor includes a cleaner that comes into contact with a lower surface of the substrate to clean the lower surface of the substrate, and the holding controller controls the substrate holder such that the center portion of the substrate is displaced in the upward direction or the downward direction in a period during which the cleaner cleans a lower-surface center portion of the substrate. Because the center portion of the substrate is displaced in the upward direction or the downward direction in the period during which the cleaner cleans the lower-surface center region of the substrate, the contact surface in which the cleaner and the substrate come into contact with each other is varied due to the displacement of the substrate. Therefore, the lower-surface center region of the substrate can be efficiently cleaned.

(5) A displacement sensor that detects displacement of the substrate is further included, and the holding controller controls the substrate holder such that displacement of the substrate falls within a predetermined range. Therefore, the substrate can be prevented from being damaged.

(6) A substrate holder that holds an outer peripheral end of a substrate, a displacement sensor that detects displacement of a center portion of the substrate, and a holding controller that controls the substrate holder such that the center portion of the substrate is displaced in an upward direction or a downward direction are included, and the holding controller, based on displacement detected by the displacement sensor, displaces the center portion of the substrate in the upward direction or the downward direction such that displacement of the center portion of the substrate held by the substrate holder falls within a predetermined range. Therefore, the substrate can be displaced to have a shape suitable for the process by displacement of the center portion of the substrate in the upward direction or the downward direction during the process for the substrate. As a result, it is possible to provide the substrate processing apparatus that can efficiently process the substrate.

(7) A substrate processing method is to be performed in a substrate processing apparatus including a substrate holder that holds an outer peripheral end of a substrate, and a processor that processes a front surface or a back surface of the substrate, and the substrate processing method includes a holding control step of controlling the substrate holder such that a center portion of the substrate is displaced in an upward direction or a downward direction in a period during which the substrate is processed by the processor. Therefore, it is possible to provide the substrate processing method with which the substrate can be efficiently processed.

(8) A substrate processing method is to be performed in a substrate processing apparatus, wherein the substrate processing apparatus includes a substrate holder that holds an outer peripheral end of a substrate, and a displacement sensor that detects displacement of a center portion of the substrate, and a holding controller that controls the substrate holder such that the center portion of the substrate is displaced in an upward direction or a downward direction, and the substrate processing method includes controlling the substrate holder, based on displacement detected by the displacement sensor, to displace the center portion of the substrate in the upward direction or the downward direction such that displacement of the center portion of the substrate held by the substrate holder falls within a predetermined range. Therefore, it is possible to provide the substrate processing method with which the substrate can be efficiently processed.

### Advantageous Effects of Invention

With the present invention, it is possible to efficiently process a substrate.

### BRIEF DESCRIPTION OF THE DRAWINGS

FIG. 1 is a schematic plan view of a substrate cleaning device according to one embodiment of the present invention.

FIG. 2 is an external perspective view showing the inner configuration of the substrate cleaning device 1.

FIG. 3 is an external perspective view of a pair of upper holding devices.

FIG. 4 is an external perspective view of an upper chuck.

FIG. 5 is a block diagram showing the configuration of a control system of the substrate cleaning device

FIG. 6 is a schematic diagram for explaining the schematic operation of the substrate cleaning device.

FIG. 7 is a diagram schematically showing the positional relationship between a substrate and a lower-surface brush with the substrate not displaced.

FIG. 8 is a diagram showing one example of the contact surface in which the substrate and the lower-surface brush come into contact with each other with the substrate not displaced.

FIG. 9 is a diagram schematically showing the positional relationship between the substrate and the lower-surface brush with the substrate displaced to a position lower than a reference position.

FIG. 10 is a diagram showing one example of the contact surface in which the substrate and the lower-surface brush come into contact with each other with the substrate displaced to a position lower than the reference position.

FIG. 11 is a diagram schematically showing the positional relationship between the substrate and the lower-surface brush with the substrate displaced to a position higher than the reference position.

FIG. 12 is a diagram showing one example of the contact surface in which the substrate and the lower-surface brush come into contact with each other with the substrate displaced to a position higher than the reference position.

FIG. 13 is a time chart showing one example of the change of a pressing force.

FIG. 14 is a flowchart showing one example of a flow of a pressing force control process.

FIG. 15 is an external perspective view showing the inner configuration of a substrate cleaning device in a second embodiment.

FIG. 16 is an external perspective view of a pair of upper holding devices in the second embodiment.

FIG. 17 is a front view schematically showing the pair of upper holding devices in the second embodiment.

FIG. 18 is a first time chart showing one example of the change of rotation angles of an upper roller and a lower roller.

FIG. 19 is a flowchart showing one example of a flow of a substrate displacement control process.

FIG. 20 is a time chart showing one example of the change of rotation angles of an upper roller and a lower roller in a first modified example.

FIG. 21 is a flowchart showing one example of a flow of a substrate displacement control process in the first modified example.

FIG. 22 is a front view schematically showing one example of a modified example of the pair of upper holding devices.

FIG. 23 is an external perspective view showing the inner configuration of a substrate cleaning device 1 in a third embodiment.

FIG. 24 is a flowchart showing one example of a flow of a substrate displacement control process in the third embodiment.

### DESCRIPTION OF EMBODIMENTS

A substrate processing apparatus and a substrate processing method according to embodiments of the present invention will be described below with reference to the drawings. In the following description, a substrate cleaning device and a substrate cleaning method are described as one example of the substrate processing apparatus and the substrate processing method. Further, a substrate refers to a semiconductor substrate, a substrate for an FPD (Flat Panel Display) such as or a liquid crystal display device an organic EL (Electroluminescence) display device, a substrate for an optical disc, a substrate for a magnetic disc, a substrate for a magneto-optical disc, a substrate for a photomask, a ceramic substrate, a substrate for a solar battery, or the like. Further, as for a substrate to be used in the present embodiment, at least part of the substrate has a circular outer periphery. For example, the outer periphery except for a notch for positioning is circular.

### First Embodiment

### 1. Configuration of Substrate Cleaning Device

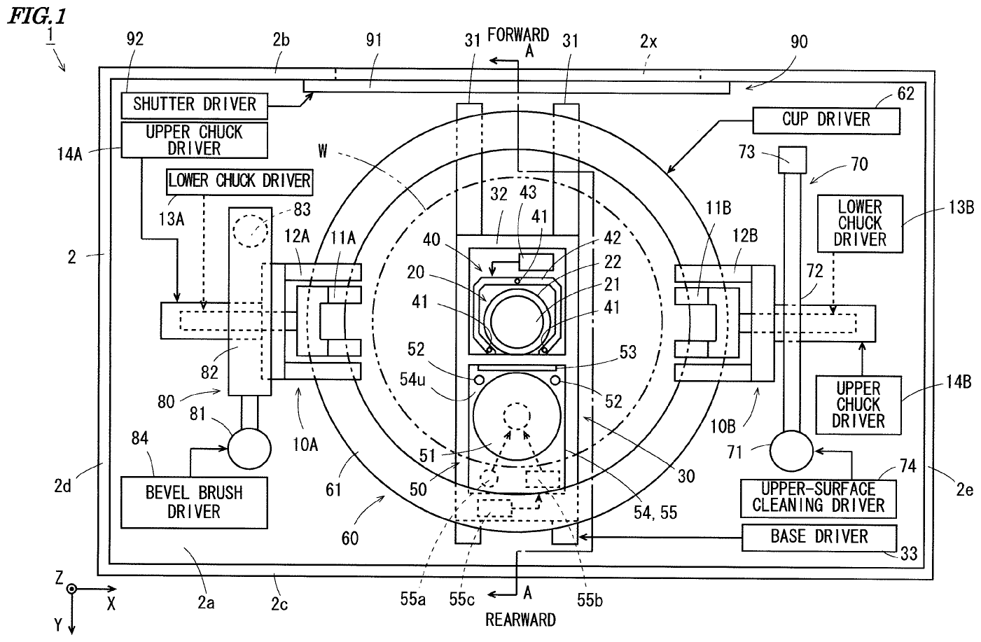

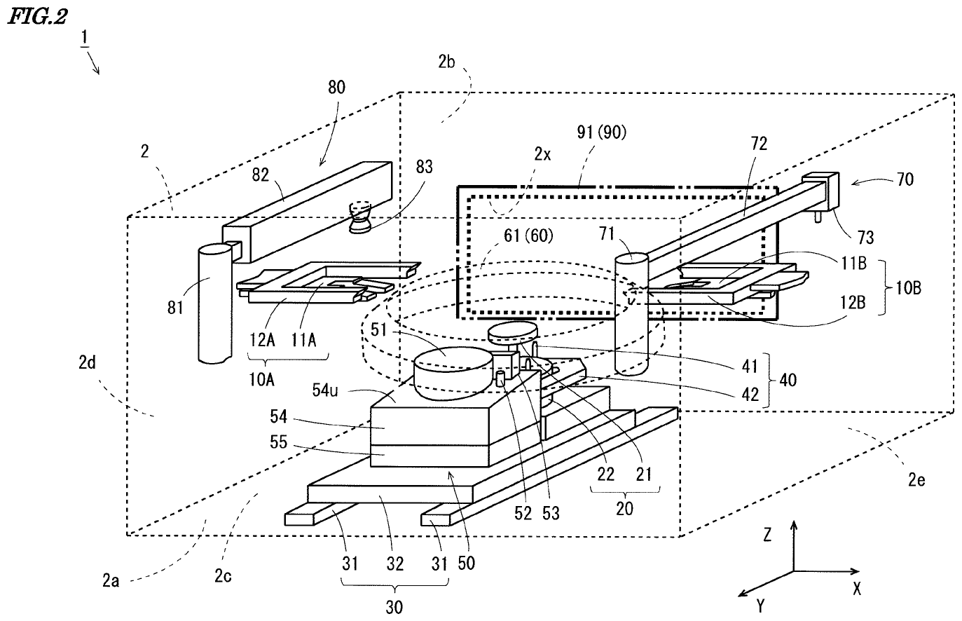

FIG. 1 is a schematic plan view of a substrate cleaning device according to one embodiment of the present invention. FIG. 2 is an external perspective view showing the inner configuration of the substrate cleaning device 1. In the substrate cleaning device 1 according to the present embodiment, X, Y and Z directions orthogonal to one another are defined for the clarity of a positional relationship. In FIG. 1 and the subsequent drawings, the X, Y and Z directions are suitably indicated by arrows. The X and Y directions are orthogonal to each other within a horizontal plane, and the Z direction corresponds to a vertical direction.

As shown in FIG. 1, the substrate cleaning device 1 includes upper holding devices 10A, 10B, a lower holding device 20, a base device 30, a receiving-transferring device 40, a lower-surface cleaning device 50, a cup device 60, an upper-surface cleaning device 70, an end-portion cleaning device 80 and an opening-closing device 90. These constituent elements are provided in a unit casing 2. In FIG. 2, the unit casing 2 is indicated by the dotted lines.

The unit casing 2 has a rectangular bottom surface portion 2a, and four sidewall portions 2b, 2c, 2d, 2e extending upwardly from the four sides of the bottom surface portion 2a. The sidewall portions 2b, 2c are opposite to each other, and the sidewall portions 2d, 2e are opposite to each other. A rectangular opening is formed in the center portion of the sidewall portion 2b. This opening is an inlet-outlet port 2x for a substrate W and is used when the substrate W is carried into and carried out from the unit casing 2. In FIG. 2, the inlet-outlet port 2x is indicated by the thick dotted lines. In the following description, a direction directed outwardly of the unit casing 2 in the Y direction from the inside of the unit casing 2 through the inlet-outlet port 2x (the direction directed from the sidewall portion 2c toward the sidewall portion 2b) is referred to as forward, and its opposite direction (the direction directed from the sidewall portion 2b toward the sidewall portion 2c) is referred to as rearward.

The opening-closing device 90 is provided in a portion in which the inlet-outlet port 2x is formed and its vicinal region in the sidewall portion 2b. The opening-closing device 90 includes a shutter 91 that is configured to be capable of opening and closing the inlet-outlet port 2x and a shutter driver 92 that drives the shutter 91. In FIG. 2, the shutter 91 is indicated by the thick two-dots and dash lines. The shutter driver 92 drives the shutter 91 to open the inlet-outlet port 2x when the substrate W is carried into and carried out from the substrate cleaning device 1. Further, the shutter driver 92 drives the shutter 91 to close the inlet-outlet port 2x when the substrate W is cleaned in the substrate cleaning device 1.

The base device 30 is provided in the center portion of the bottom surface portion 2a. The base device 30 includes linear guides 31, a mobile base 32 and a base driver 33. The linear guides 31 include two rails and are provided to extend in the Y direction from the positions in the vicinity of the sidewall portion 2b to the positions in the vicinity of the sidewall portion 2c in plan view. The mobile base 32 is provided to be movable in the Y direction on the two rails of the linear guides 31. The base driver 33 includes a pulse motor, for example, and moves the mobile base 32 in the Y direction on the linear guides 31.

The lower holding device 20 and the lower-surface cleaning device 50 are provided on the mobile base 32 to be arranged in the Y direction. The lower holding device 20 includes a suction holder 21 and a suction holding driver 22. The suction holder 21 is a so-called spin chuck, has a circular suction surface that can hold a lower surface of the substrate W by suction and is configured to be rotatable about an axis extending in the upward-and-downward direction (the axis extending in the Z direction). In the following description, a region that is to be sucked by the suction surface of the suction holder 21 in the lower surface of the substrate W when the substrate W is held by suction by the suction holder 21 is referred to as a lower-surface center region. On the other hand, a region, surrounding the lower-surface center region, in the lower surface of the substrate W is referred to as a lower-surface outer region.

The suction holding driver 22 includes a motor. The motor of the suction holding driver 22 is provided on the mobile base 32 such that its rotation shaft projects upwardly. The suction holder 21 is attached to upper end portion of the rotation shaft of the suction holding driver 22. Further, in the rotation shaft of the suction holding driver 22, a suction path for holding the substrate W by suction in the suction holder 21 is formed. The suction path is connected to a suction device (not shown). The suction holding driver 22 rotates the suction holder 21 about the above-mentioned rotation shaft.

On the mobile base 32, the receiving-transferring device 40 is further provided in the vicinity of the lower holding device 20. The receiving-transferring device 40 includes a plurality (three in the present example) of support pins 41, a pin coupling member 42 and a pin lifting-lowering driver 43. The pin coupling member 42 is formed to surround the suction holder 21 in plan view and couples the plurality of support pins 41 to one another. The plurality of support pins 41 extend upwardly by a certain length from the pin coupling member 42 while being coupled to one another by the pin coupling member 42. The pin lifting-lowering driver 43 lifts and lowers the pin coupling member 42 on the mobile base 32. Thus, the plurality of support pins 41 are lifted and lowered relative to the suction holder 21.

The lower-surface cleaning device 50 includes a lower-surface brush 51, two liquid nozzles 52, a gas injector 53, a lifting-lowering supporter 54, a movement supporter 55, a lower-surface brush operation driver 55a, a lower-surface brush lifting-lowering driver 55b and a lower-surface brush movement driver 55c. The movement supporter 55 is provided to be movable in the Y direction with respect to the lower holding device 20 in a certain region on the mobile base 32. As shown in FIG. 2, the lifting-lowering supporter 54 is provided on the movement supporter 55 to be liftable and lowerable. The lifting-lowering supporter 54 has an upper surface 54u that is inclined downwardly in a direction away from the suction holder 21 (rearwardly in the present example).

As shown in FIG. 1, the lower-surface brush 51 has a circular outer shape in plan view and is formed to be relatively large in the present embodiment. Specifically, the diameter of the lower-surface brush 51 is larger than the diameter of the suction surface of the suction holder 21 and is 1.3 times of the diameter of the suction surface of the suction holder 21, for example. Further, the diameter of the lower-surface brush 51 is larger than ⅓ of the diameter of the substrate W and smaller than ½ of the diameter of the substrate W. The diameter of the substrate W is 300 mm, for example.

The lower-surface brush 51 has a cleaning surface that can come into contact with the lower surface of the substrate W. Further, the lower-surface brush 51 is attached to the upper surface 54u of the lifting-lowering supporter 54 such that the cleaning surface is directed upwardly and is rotatable about an axis extending in the upward-and-downward direction through the center of the cleaning surface.

Each of the two liquid nozzles 52 is attached to the upper surface 54u of the lifting-lowering supporter 54 to be located in the vicinity of the lower-surface brush 51. Further, each of the two liquid nozzles 52 is attached to the upper surface 54u such that a liquid discharge port is directed upwardly. A lower-surface cleaning liquid supplier 56 (FIG. 5) is connected to the liquid nozzles 52. The lower-surface cleaning liquid supplier 56 supplies a cleaning liquid to the liquid nozzles 52. When the substrate W is cleaned by the lower-surface brush 51, the liquid nozzles 52 discharge the cleaning liquid supplied from the lower-surface cleaning liquid supplier 56 to the lower surface of the substrate W. In the present embodiment, pure water is used as the cleaning liquid to be supplied to the liquid nozzles 52.

The gas injector 53 is a slit-like gas injection nozzle having a gas injection port extending in one direction. The gas injector 53 is attached to the upper surface 54u of the lifting-lowering supporter 54 to be located between the lower-surface brush 51 and the suction holder 21 in plan view. Further, the gas injector 53 is attached to the upper surface 54u of the lifting-lowering supporter 54 such that a gas injection port is directed upwardly. An injection gas supplier 57 (FIG. 5) is connected to the gas injector 53. The injection gas supplier 57 supplies gas to the gas injector 53. In the present embodiment, an inert gas such as a nitrogen gas is used as the gas to be supplied to the gas injector 53. The gas injector 53 injects the gas supplied from the injection gas supplier 57 to the lower surface of the substrate W during cleaning of the substrate W by the lower-surface brush 51 and during drying of the lower surface of the substrate W, as described below. In this case, a strip-shaped gas curtain extending in the X direction is formed between the lower-surface brush 51 and the suction holder 21.

The lower-surface brush operation driver 55a includes an air cylinder and an electropneumatic regulator that drives the air cylinder. When the substrate W is cleaned by the lower-surface brush 51, the lower-surface brush operation driver 55a controls the electropneumatic regulator to drive the air cylinder and controls a force with which the lower-surface brush 51 is pressed against the lower surface of the substrate W.

Further, the lower-surface brush operation driver 55a further includes a motor, and drives the motor with the lower-surface brush 51 being in contact with the lower surface of the substrate W when the substrate W is cleaned by the lower-surface brush 51. Thus, the lower-surface brush 51 is rotated. Details of the lower-surface brush operation driver 55a will be described below.

The lower-surface brush lifting-lowering driver 55b includes a stepping motor or an air cylinder, and lifts and lowers the lifting-lowering supporter 54 with respect to the movement supporter 55. The lower-surface brush movement driver 55c includes a motor, and moves the movement supporter 55 in the Y direction on the mobile base 32. Here, the position of the lower holding device 20 in the mobile base 32 is fixed. Therefore, when being moved by the lower-surface brush movement driver 55c in the Y direction, the movement supporter 55 is moved relative to the lower holding device 20. In the following description, the position of the lower-surface cleaning device 50 being located closest to the lower holding device 20 on the mobile base 32 is referred to as a proximal position, and the position of the lower-surface cleaning device 50 being located farthest from the lower holding device 20 on the mobile base 32 is referred to as a distal position.

The cup device 60 is further provided in the center portion of the bottom surface portion 2a. The cup device 60 includes a cup 61 and a cup driver 62. The cup 61 is provided to surround the lower holding device 20 and the base device 30 in plan view, and be liftable and lowerable. In FIG. 2, the cup 61 is indicated by the dotted lines. The cup driver 62 moves the cup 61 between a lower cup position and an upper cup position in accordance with which portion of the lower surface of the substrate W is to be cleaned by the lower-surface brush 51. The lower cup position is a height position at which the upper end portion of the cup 61 is located farther downwardly than the substrate W held by suction by the suction holder 21. Further, the upper cup position is a height position at which the upper end portion of the cup 61 is located farther upwardly than the suction holder 21.

At height positions farther upward than the cup 61, the pair of upper holding devices 10A, 10B are provided to be opposite to each other with the base device 30 held therebetween in plan view. The upper holding device 10A includes a lower chuck 11A, an upper chuck 12A, a lower chuck driver 13A and an upper chuck driver 14A. The upper holding device 10B includes a lower chuck 11B, an upper chuck 12B, a lower chuck driver 13B and an upper chuck driver 14B. The upper holding devices 10A, 10B form a substrate alignment device of the present invention.

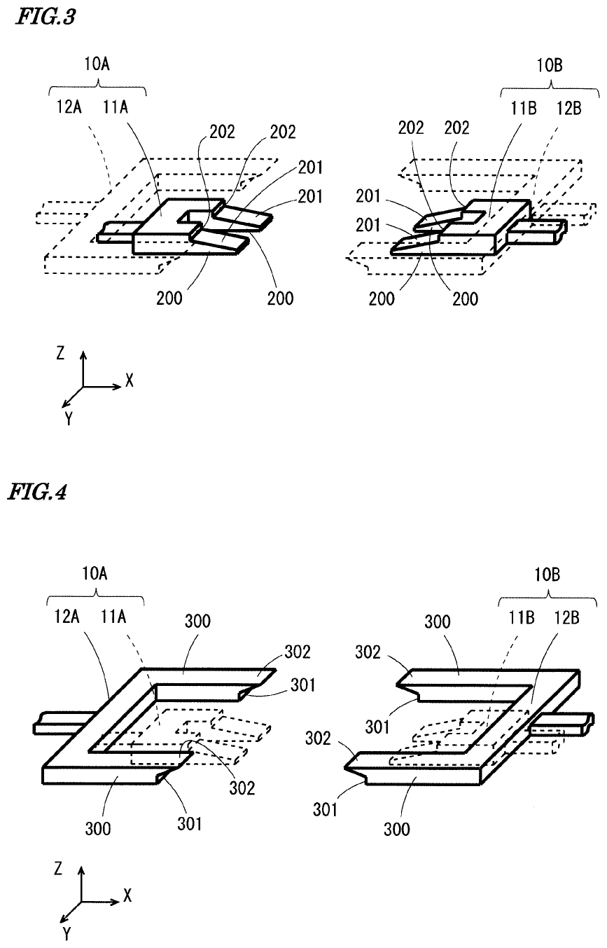

FIG. 3 is an external perspective view of the pair of upper holding devices. In FIG. 3, the lower chucks 11A, 11B are indicated by the thick solid lines. Further, the upper chucks 12A, 12B are indicated by the dotted lines. In regard to the external perspective view of FIG. 3, the expansion and contraction rates of each component are different from those in FIG. 2 in order to facilitate understanding of the shapes of the lower chucks 11A, 11B.

As shown in FIG. 3, the lower chucks 11A, 11B are arranged symmetrically with respect to a vertical plane extending in the Y direction (a forward-and-rearward direction) through the center of the suction holder 21 in plan view, and are provided to be movable in the X direction in a common horizontal plane. Each of the lower chucks 11A, 11B has two support pieces 200. Each support piece 200 is provided with an inclined support surface 201 and a movement limiting surface 202.

In the lower chuck 11A, the inclined support surface 201 of each support piece 200 is formed so as to be capable of supporting the outer peripheral end of the substrate W from below and extend obliquely downwardly toward the lower chuck 11B. The movement limiting surface 202 extends upwardly by a certain distance from the upper end of the inclined support surface 201 to generate a level difference at the upper end of the lower chuck 11A. On the other hand, in the lower chuck 11B, the inclined support surface 201 of each support piece 200 is formed so as to be capable of supporting the outer peripheral end of the substrate W from below and extend obliquely downwardly toward the lower chuck 11A. The movement limiting surface 202 extends upwardly from the upper end of the inclined support surface 201 to generate a level difference at the upper end of the lower chuck 11B.

The lower chuck drivers 13A, 13B include air cylinders or motors as actuator. The lower chuck drivers 13A, 13B move the lower chucks 11A, 11B such that the lower chucks 11A, 11B are closer to each other or are farther away from each other. Here, in a case in which the target positions of the lower chucks 11A, 11B in the X direction are predetermined, the lower chuck drivers 13A, 13B can respectively adjust the positions of the lower chucks 11A, 11B in the X direction based on the information about the target positions. For example, it is possible to place the substrate W on the plurality of inclined support surfaces 201 of the lower chucks 11A, 11B by making the distance between the lower chucks 11A, 11B be smaller than the outer diameter of the substrate W. In this case, the outer peripheral end of the substrate W is supported by each inclined support surface 201.

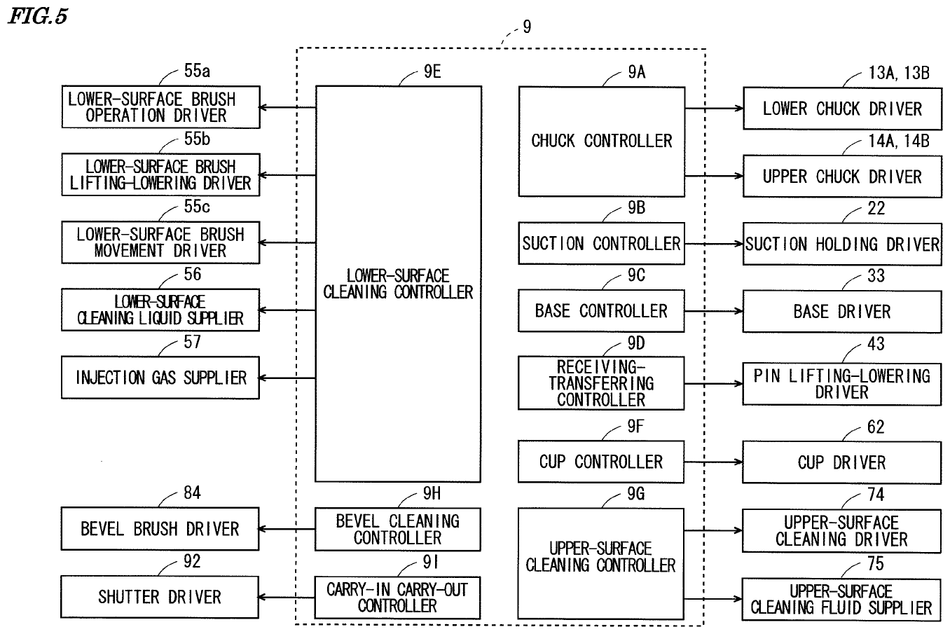

FIG. 4 is an external perspective view of the upper chucks 12A, 12B of FIGS. 1 and 2. In FIG. 4, the upper chucks 12A, 12B are indicated by the thick solid lines. Further, the lower chucks 11A, 11B are indicated by the dotted lines. In regard to the external perspective view of FIG. 4, the expansion and contraction rates of each component are different from those in the external perspective view of FIG. 2 in order to facilitate understanding of the shapes of the upper chucks 12A, 12B.

As shown in FIG. 4, similarly to the lower chucks 11A, 11B, the upper chucks 12A, 12B are arranged symmetrically with respect to the vertical plane extending in the Y direction (the forward-and-rearward direction) through the center of the suction holder 21 in plan view, and are provided to be movable in the X direction in a common horizontal plane. Each of the upper chucks 12A, 12B has two holding pieces 300. Each holding piece 300 has an abutment surface 301 and a projection 302.

In the upper chuck 12A, the abutment surface 301 of each holding piece 300 is formed so as to face the upper chuck 12B at the lower portion of the tip of the holding piece 300, and is orthogonal to the X direction. The projection 302 is formed so as to project from the upper end of the abutment surface 301 toward the upper chuck 12B by a predetermined distance. On the other hand, in the upper chuck 12B, the abutment surface 301 of each holding piece 300 is formed so as to face the upper chuck 12A at the lower portion of the tip of the holding piece 300, and is orthogonal to the X direction. The projection 302 is formed so as to project from the upper end of the abutment surface 301 toward the upper chuck 12A by a predetermined distance.

The upper chuck drivers 14A, 14B include air cylinders or motors as actuators. The upper chuck drivers 14A, 14B move the upper chucks 12A, 12B such that the upper chucks 12A, 12B are closer to each other or farther away from each other. Here, in a case in which the target positions of the upper chucks 12A, 12B in the X direction are predetermined, the upper chuck drivers 14A, 14B can respectively adjust the positions of the upper chucks 12A, 12B in the X direction based on the information about the target positions.

In the above-mentioned upper holding devices 10A, 10B, the upper chucks 12A, 12B are moved toward the outer peripheral end of the substrate W supported by the lower chucks 11A, 11B. The two abutment surfaces 301 of the upper chuck 12A and the two abutment surfaces 301 of the upper chuck 12B come into contact with a plurality of portions of the outer peripheral end of the substrate W, whereby the outer peripheral end of the substrate W is held and the substrate W is firmly fixed.

As shown in FIG. 1, at a position near one side of the cup 61, the upper-surface cleaning device 70 is provided to be located in the vicinity of the upper holding device 10B in plan view. The upper-surface cleaning device 70 includes a rotation support shaft 71, an arm 72, a spray nozzle 73 and an upper-surface cleaning driver 74.

The rotation support shaft 71 is supported on the bottom surface portion 2a by the upper-surface cleaning driver 74 to extend in the upward-and-downward direction, and to be liftable, lowerable and rotatable. As shown in FIG. 2, at a position farther upward than the upper holding device 10B, the arm 72 is provided to extend in the horizontal direction from the upper end portion of the rotation support shaft 71. The spray nozzle 73 is attached to the tip portion of the arm 72.

An upper-surface cleaning fluid supplier 75 (FIG. 5) is connected to the spray nozzle 73. The upper-surface cleaning fluid supplier 75 supplies a cleaning liquid and gas to the spray nozzle 73. In the present embodiment, pure water is used as the cleaning liquid to be supplied to the spray nozzle 73, and an inert gas such as a nitrogen gas is used as the gas to be supplied to the spray nozzle 73. When the upper surface of the substrate W is cleaned, the spray nozzle 73 mixes the cleaning liquid and the gas supplied from the upper-surface cleaning fluid supplier 75 to produce a fluid mixture, and injects the produced fluid mixture downwardly.

The upper-surface cleaning driver 74 includes one or a plurality of pulse motors, an air cylinder and the like, lifts and lowers the rotation support shaft 71, and rotates the rotation support shaft 71. With the above-mentioned configuration, on the upper surface of the substrate W held by suction and rotated by the suction holder 21, the spray nozzle 73 is moved in a circular arc shape. Thus, the entire upper surface of the substrate W can be cleaned.

As shown in FIG. 1, at a position near the other side of the cup 61, the end-portion cleaning device 80 is provided to be located in the vicinity of the upper holding device 10A in plan view. The end-portion cleaning device 80 includes a rotation support shaft 81, an arm 82, a bevel brush 83 and a bevel brush driver 84.

The rotation support shaft 81 is supported on the bottom surface portion 2a by the bevel brush driver 84 to extend in the upward-and-downward direction and to be liftable, lowerable and rotatable. As shown in FIG. 2, at a position farther upward than the upper holding device 10A, the arm 82 is provided to extend in the horizontal direction from the upper end portion of the rotation support shaft 81. At the tip portion of the arm 82, the bevel brush 83 is provided to project downwardly and to be rotatable about an axis extending in the upward-and-downward direction.

In the bevel brush 83, its upper half portion has an inverse trapezoidal shape, and its lower half portion has a trapezoidal shape. With this bevel brush 83, the outer peripheral end of the substrate W can be cleaned by the center portion in the upward-and-downward direction of the outer peripheral surface.

The bevel brush driver 84 includes one or a plurality of pulse motors, an air cylinder and the like, lifts and lowers the rotation support shaft 81 and rotates the rotation support shaft 81. With the above-mentioned configuration, the center portion of the outer peripheral surface of the bevel brush 83 is brought into contact with the outer peripheral end of the substrate W held by suction and rotated by the suction holder 21. Thus, the entire outer peripheral end of the substrate W can be cleaned.

Here, the bevel brush driver 84 further includes a motor built in the arm 82. The motor rotates the bevel brush 83 provided at the tip portion of the arm 82 about the axis extending in the upward-and-downward direction. Therefore, when the outer peripheral end of the substrate W is cleaned, a cleaning force of the bevel brush 83 in the outer peripheral end of the substrate W is improved by rotation of the bevel brush 83.

FIG. 5 is a block diagram showing the configuration of a control system of the substrate cleaning device 1. The control device 9 of FIG. 5 includes a CPU (Center Processing Unit), a RAM (Random Access Memory), a ROM (Read Only Memory) and a storage device. The RAM is used as a work area for the CPU. The ROM stores a system program. The storage device stores a control program.

As shown in FIG. 5, the control device 9 includes a chuck controller 9A, a suction controller 9B, a base controller 9C, a receiving-transferring controller 9D, a lower-surface cleaning controller 9E, a cup controller 9F, an upper-surface cleaning controller 9G, a bevel cleaning controller 9H and a carry-in carry-out controller 9I as functions. The functions of the control device 9 are implemented by execution of a substrate cleaning program stored in the storage device by the CPU. Part or all of the functions of the control device 9 may be implemented by hardware such as an electronic circuit.

The chuck controller 9A controls the lower chuck drivers 13A, 13B and the upper chuck drivers 14A, 14B in order to receive the substrate W that is carried into the substrate cleaning device 1 and hold the substrate W at a position above the suction holder 21. The suction controller 9B controls the suction holding driver 22 in order to hold the substrate W by suction using the suction holder 21 and rotate the substrate W held by suction.

The base controller 9C controls the base driver 33 in order to move the mobile base 32 with respect to the substrate W held by the upper holding devices 10A, 10B. The receiving-transferring controller 9D controls the pin lifting-lowering driver 43 in order to move the substrate W between a height position of the substrate W held by the upper holding devices 10A, 10B and a height position of the substrate W held by the suction holder 21.

The lower-surface cleaning controller 9E controls the lower-surface brush operation driver 55a, the lower-surface brush lifting-lowering driver 55b, the lower-surface brush movement driver 55c, the lower-surface cleaning liquid supplier 56 and the injection gas supplier 57 in order to clean the lower surface of the substrate W. The cup controller 9F controls the cup driver 62 in order for the cup 61 to receive the cleaning liquid splashed from the substrate W when the substrate W held by suction by the suction holder 21 is cleaned.

The upper-surface cleaning controller 9G controls the upper-surface cleaning driver 74 and the upper-surface cleaning fluid supplier 75 in order to clean the upper surface of the substrate W held by suction by the suction holder 21. The bevel cleaning controller 9H controls the bevel brush driver 84 for cleaning of the outer peripheral end of the substrate W held by suction by the suction holder 21. The carry-in carry-out controller 9I controls the shutter driver 92 in order to open and close the inlet-outlet port 2x of the unit casing 2 when the substrate W is carried into and carried out from the substrate cleaning device 1.

### 2. Schematic Operation of Substrate Cleaning Device During Cleaning for Lower-Surface Center Region

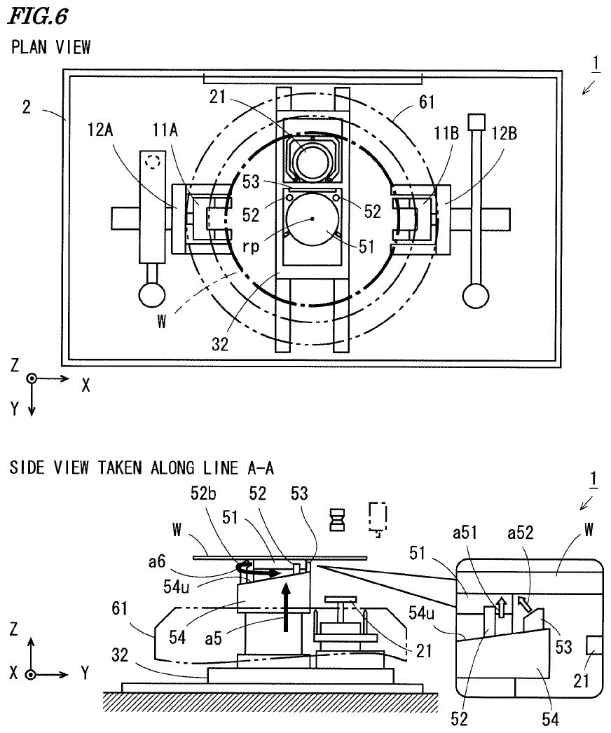

FIG. 6 is a schematic diagram for explaining the schematic operation of the substrate cleaning device 1. In FIG. 6, a plan view of the substrate cleaning device 1 is shown in the upper field. Further, the side view of the lower holding device 20 and its peripheral portions as viewed in the Y direction is shown in the bottom field. The side view in the bottom field corresponds to the side view of the substrate cleaning device 1 taken along the line A-A of FIG. 1. The expansion and contraction rates of part of the constituent elements are different for the plan view in the upper field and the side view in the bottom field in order to facilitate understanding of the shape and operation state of each constituent element in the substrate cleaning device 1. Further, the cup 61 is indicated by the two-dots and dash lines, and the outer shape of the substrate W is indicated by the thick one-dot and dash lines.

With reference to FIG. 6, as indicated by the thick solid arrow a5, the lifting-lowering supporter 54 is lifted such that the cleaning surface of the lower-surface brush 51 comes into contact with the lower-surface center region of the substrate W. Further, as indicated by the thick solid arrow a6, the lower-surface brush 51 is rotated (spins) about the axis extending in the upward-and-downward direction. Thus, contaminants adhering to the lower-surface center region of the substrate W are physically stripped by the lower-surface brush 51.

In the bottom field in FIG. 6, the enlarged side view of a portion in which the lower-surface brush 51 come into contact with the lower surface of the substrate W is shown in a balloon. As shown in the balloon, with the lower-surface brush 51 in contact with the substrate W, the liquid nozzle 52 and the gas injector 53 are held at positions close to the lower surface of the substrate W. At this time, as indicated by the outlined arrow a51, the liquid nozzle 52 discharges the cleaning liquid toward the lower surface of the substrate W at a position in the vicinity of the lower-surface brush 51. Thus, the cleaning liquid that has been supplied to the lower surface of the substrate W from the liquid nozzle 52 is guided to the contact portion in which the lower-surface brush 51 and the substrate W come into contact with each other, whereby contaminants that have been removed from the back surface of the substrate W by the lower-surface brush 51 are washed away by the cleaning liquid. In this manner, in the lower-surface cleaning device 50, the liquid nozzle 52 is attached to the lifting-lowering supporter 54 together with the lower-surface brush 51. Thus, the cleaning liquid can be supplied efficiently to a portion to be cleaned in the lower surface of the substrate W by the lower-surface brush 51. Therefore, the consumption of the cleaning liquid is reduced, and excessive splashing of the cleaning liquid is suppressed.

Next, in the state shown in FIG. 6, when the cleaning of the lower-surface center region of the substrate W is completed, the rotation of the lower-surface brush 51 is stopped, and the lifting-lowering supporter 54 is lowered such that the cleaning surface of the lower-surface brush 51 is spaced apart from the substrate W by a predetermined distance. Further, discharging of the cleaning liquid from the liquid nozzle 52 to the substrate W is stopped. At this time, the injection of gas from the gas injector 53 to the substrate W continues.

### 3. Control of Pressing Forces To Be Applied by Pair Of Upper Holding Devices

In the present embodiment, the substrate W is firmly fixed because the pair of upper holding devices 10A, 10B that are arranged to be opposite to each other with the substrate W held therebetween in plan view hold the substrate W. Because the substrate W has a predetermined weight, the substrate W is curved due to gravity. In this case, downward displacement of the center portion of the substrate W is maximized. Further, when the pressing forces of the pair of upper holding devices 10A, 10B pressing the substrate W in the directions in which the pair of upper holding devices 10A, 10B sandwich the substrate W therebetween are increased, the downward displacement of the center portion of the substrate W is increased. Therefore, an amount of downward displacement of the center portion of the substrate W is adjusted by adjustment of the pressing forces. The adjustment of the pressing forces is equivalent to the adjustment of the distance between the upper holding devices 10A, 10B. Specifically, the pressing forces are increased when the upper chucks 12A, 12B are moved by the upper chuck drivers 14A, 14B to be close to each other, and the pressing forces are decreased when the upper chucks 12A, 12B are moved by the upper chuck drivers 14A, 14B to be farther away from each other.

On the other hand, in a period during which the lower-surface brush 51 cleans the lower-surface center region of the substrate W, the lower-surface brush 51 is pressed against the lower surface of the substrate W. At this time, whether the center portion of the substrate W is displaced is defined by the resultant force of the gravity applied to the substrate W and the force received by the substrate W from the upper holding devices 10A, 10B, and the uplift force applied to the lower-surface brush 51.

In the substrate cleaning device 1 in the present embodiment, in a period during which the lower-surface brush 51 cleans the lower-surface center region of the substrate W, the lower-surface brush operation driver 55a makes the uplift force for uplifting the lower-surface brush 51 against the lower-surface of the substrate W be constant. Therefore, the upper chuck drivers 14A, 14B change the distance between the upper chucks 12A, 12B to adjust the pressing forces, so that the amount of displacement of the center portion of the substrate W is adjusted. Here, with the position at which the substrate W is held by the pair of upper holding devices 10A, 10B as a reference position, an amount of displacement is indicated by the distance in the vertical direction between the position of the center portion of the substrate W and the reference position. The value of an amount of displacement is negative when the position of the center portion of the substrate W is located at a position lower than the reference position, and is positive when the center portion of the substrate W is located at a position higher than the reference position. Further, the value of the maximum amount of displacement that allows the center portion of the substrate W to be displaced to a position higher than the reference position is referred to as an upper limit value, and the value of the minimum amount of displacement that allows the center portion of the substrate W to be displaced to a position lower than the reference position is referred to as a lower limit value.

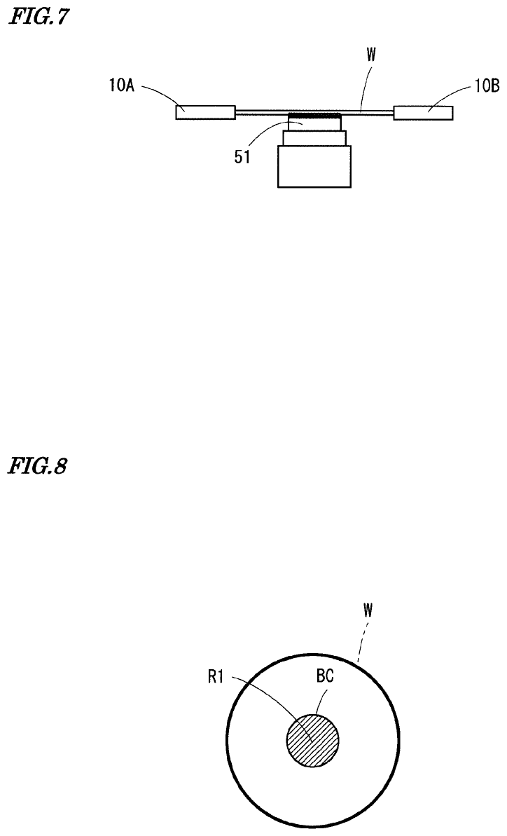

FIG. 7 is a diagram schematically showing the positional relationship between the substrate and the lower-surface brush with the substrate not being displaced. FIG. 8 is a diagram showing one example of a contact surface of the substrate that comes into contact with the lower-surface brush with the substrate not being displaced. In FIG. 7, the region in which the substrate W and the lower-surface brush 51 are in contact with each other is indicated by the thick line. In FIG. 8, the region in which the substrate W and the lower-surface brush 51 are in contact with each other is indicated by hatching.

With reference to FIGS. 7 and 8, the center portion of the substrate W is located at the reference position. In this case, the amount of displacement of the substrate W is zero, the entire substrate W is substantially horizontal, and a lower-surface center region BC of the substrate W is flat. On the other hand, the upper surface of the lower-surface brush 51 is substantially horizontal. Therefore, the lower-surface brush 51 and the substrate W are in contact with each other in an entire region R1 equivalent to the entire lower-surface center region BC. In this case, the force exerted between the lower-surface brush 51 and the lower-surface center region BC is evenly distributed to the entire region R1.

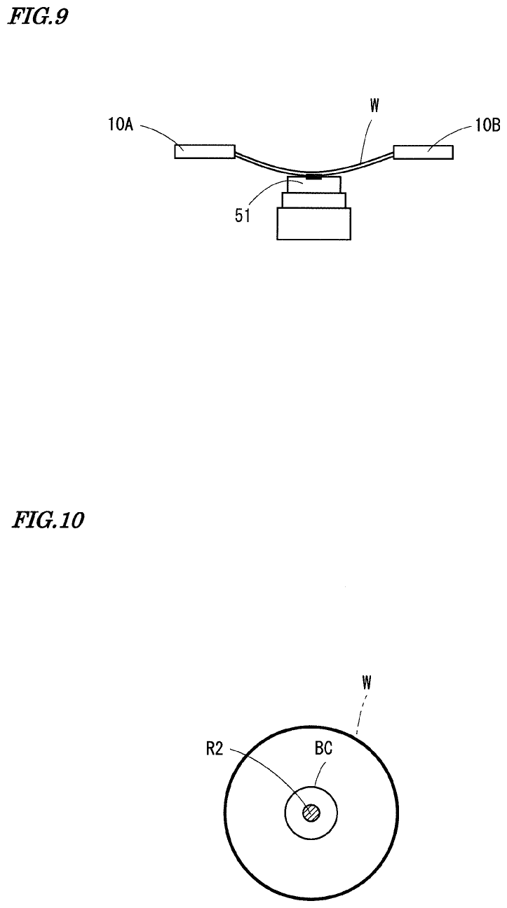

FIG. 9 is a diagram schematically showing the positional relationship between the substrate and the lower-surface brush when the value of the amount of displacement of the substrate is negative. FIG. 10 is a diagram showing one example of the contact surface of the substrate that comes into contact with the lower-surface brush when the value of the amount of displacement of the substrate is negative. In FIG. 9, the region in which the substrate W and the lower-surface brush 51 are in contact with each other is indicated by the thick line. In FIG. 10, the region in which the substrate W and the lower-surface brush 51 are in contact with each other is indicated by hatching.

With reference to FIG. 9, in a case in which the center of the substrate W is displaced to a position lower than the reference position and the value of the amount of displacement is negative, the substrate W has a downwardly protruding shape, and the lower-surface center region BC has a curved surface. On the other hand, the upper surface of the lower-surface brush 51 is substantially horizontal. Therefore, the entire upper surface of the lower-surface brush 51 does not come into contact with the substrate W. With reference to FIG. 10, the lower-surface brush 51 and the substrate W come into contact with each other in a circular or oval center region R2 in the lower-surface center region BC, and the center region R2 includes the center portion of the substrate W and has a diameter smaller than that of the lower-surface center region BC.

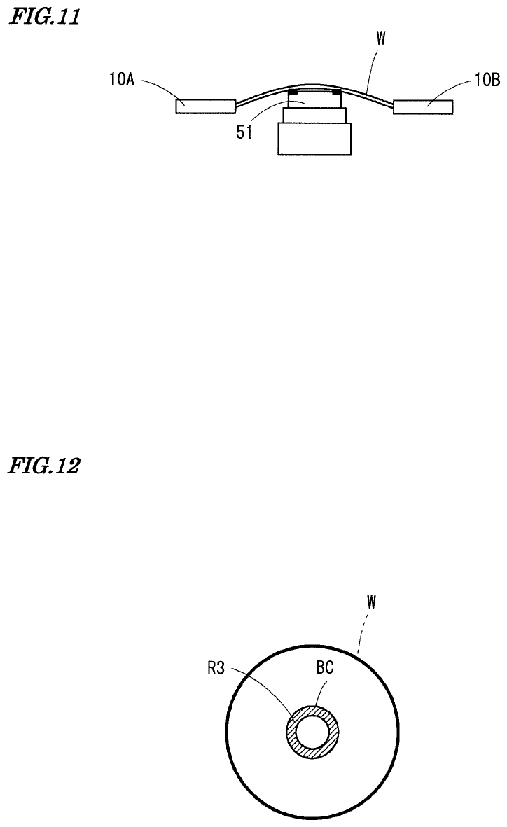

FIG. 11 is a diagram schematically showing the positional relationship between the substrate and the lower-surface brush when the value of the amount of displacement of the substrate is positive. FIG. 12 is a diagram showing one example of the contact surface of the substrate that comes into contact with the lower-surface brush when the value of the amount of displacement of the substrate is positive. In FIG. 11, the region in which the substrate W and the lower-surface brush 51 are in contact with each other is indicated by the thick lines. In FIG. 12, the region in which the substrate W and the lower-surface brush 51 are in contact with each other is indicated by hatching.

With reference to FIG. 11, in a case in which the center of the substrate W is displaced and the value of the amount of displacement is positive, the lower-surface center region has an upwardly protruding shape, and the lower-surface center region BC has a curved surface. On the other hand, the upper surface of the lower-surface brush 51 is substantially horizontal. Therefore, the entire upper surface of the lower-surface brush 51 does not come into contact with the substrate W. With reference to FIG. 12, the lower-surface brush 51 and the substrate W come into contact with each other in an annular region R3 in the lower-surface center region BC, and the annular region R3 includes the outer periphery and excludes the center portion of the substrate W.

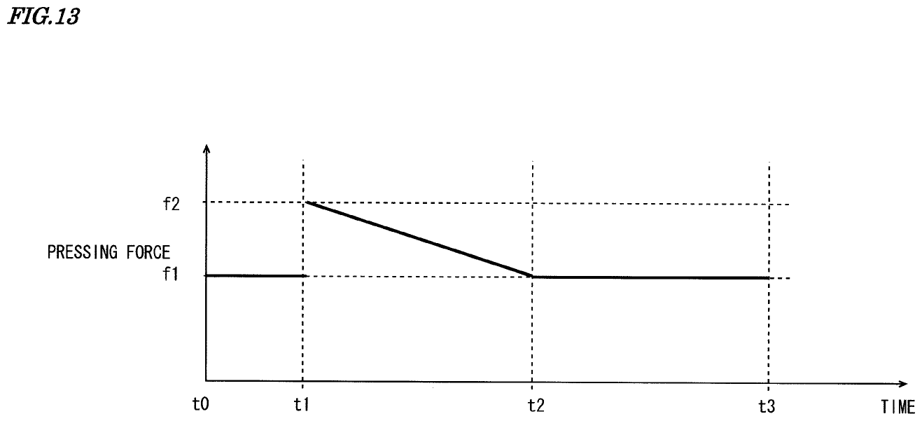

FIG. 13 is a time chart showing one example of the change of the pressing force. In the time chart of FIG. 13, the ordinate indicates the pressing force, and the abscissa indicates time.

With reference to FIG. 13, at a point to in time before cleaning of the lower-surface center region BC of the substrate W by the lower-surface brush 51 is started, the upper chuck drivers 14A, 14B control the actuators such that the substrate W is pressed with pressing forces f1. The pressing force f1 has a value determined in advance as a force with which the substrate W can be held without being rotated in the period during which the substrate W is cleaned by the lower-surface brush 51.

At a point t1 in time, the upper chuck drivers 14A, 14B control the actuators such that the substrate W is pressed with pressing forces f2. The pressing force f2 has a value predetermined such that the value of the amount of displacement of the substrate W is the lower limit value with the substrate W receiving the uplift force from the lower-surface brush 51. Therefore, at the point t1 in time, the value of the amount of displacement of the center portion of the substrate W is the lower limit value. Therefore, as shown in FIGS. 9 and 10, the center region R2 of the substrate W is cleaned by the lower-surface brush 51.

Then, in the period from the point t1 to the point t2 in time, the upper chuck drivers 14A, 14B control the actuators to reduce the pressing forces. The point t2 in time is a point in time earlier than a point t3 in time at which a cleaning period, which is predetermined as the period during which the lower-surface center region BC of the substrate W is cleaned by the lower-surface brush 51, ends. The upper chuck drivers 14A, 14B reduce the pressing forces in the period from the point t1 to the point t2 in time such that the pressing forces are the pressing forces f1 at the point t2 in time. Therefore, the force for downwardly displacing the center portion of the substrate W is gradually decreased. Because the uplift force to be applied to the lower-surface brush 51 is constant, the lower-surface brush 51 is lifted while being in contact with the substrate W. Thus, the center portion of the substrate W is lifted from the position corresponding to the lower limit value to the reference position. At the point t2 in time, the entire region R1 in the lower-surface center region BC of the substrate W comes into contact with the lower-surface brush 51. Therefore, in the period from the point t1 to the point t2 in time, the portion in which the lower-surface brush 51 and the substrate W come into contact with each other gradually spreads from the center region R2 to become the entire region R1.

In the period from the point t2 to the point t3 in time, the upper chuck drivers 14A, 14B control the actuators to maintain the pressing forces f1. Therefore, the downward force, which the lower-surface brush 51 receives from the substrate W, is constant. The uplift force applied to the lower-surface brush 51 is constant, and is set to a value larger than that of the downward force, which the lower-surface brush 51 receives from the substrate W held with the pressing forces f1. Therefore, in the period from the point t2 to the point t3 in time, the lower-surface brush 51 is lifted while being in contact with the substrate W. Thus, the center portion of the substrate W is lifted 1 from the reference position to the position corresponding to the upper limit value. At the point t3 in time, the annular region R3 in the lower-surface center region BC of the substrate W comes into contact with the lower-surface brush 51. Therefore, in the period from the point t2 to the point t3 in time, the portion in which the lower-surface brush 51 and the substrate W come into contact with each other is gradually decreased to be the annular region R3.

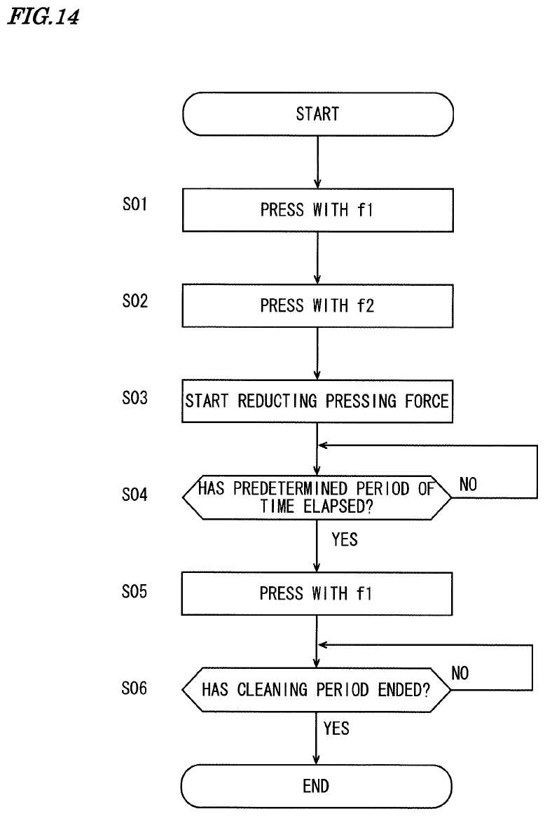

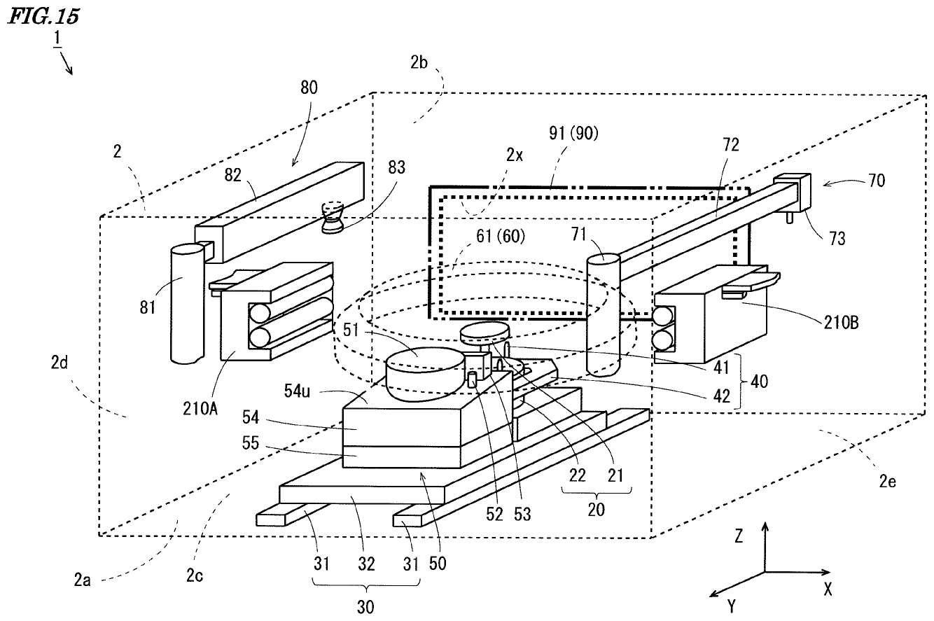

FIG. 14 is a flowchart showing one example of a flow of a pressing force control process. The pressing force control process is a process to be executed by the control device 9. With reference to FIG. 14, the control device 9 controls the upper chuck drivers 14A, 14B such that the upper chucks 12A, 12B press the substrate W with the pressing forces f1 (step S01).

In the next step S02, the control device 9 controls the upper chuck drivers 14A, 14B such that the upper chucks 12A, 12B press the substrate W with the pressing forces f2. In this stage, in the center region R2 in the lower-surface center region BC of the substrate W, the lower-surface brush 51 comes into contact with the substrate W. Therefore, the center region R2 of the substrate W is cleaned by the lower-surface brush 51.

In the step S03, the reduction of the pressing forces is started, and the process proceeds to the step S04. As shown in FIG. 13, the reduction rate is defined such that the pressing forces become the pressing forces t1 at the point t2 in time.

In the step S04, whether a predetermined period of time has elapsed since the start of cleaning is determined. The process waits until the predetermined period of time elapses since the start of cleaning (NO in the step S04). If the predetermined period of time has elapsed (YES in the step S04), the process proceeds to the step S05. The predetermined period of time is the period of time from the point t1 to the time t2 in time in FIG. 13. Therefore, the pressing forces are gradually reduced from f2 in the period from the point t1 to the point t2 in time, and becomes f1 at the point t2 in time. Because the pressing forces are gradually reduced from f2 to f1 in the period from the point t1 to the point t2 in time, the portion in which the lower-surface brush 51 and the substrate W come into contact with each other gradually spreads from the center region R2 to become the entire region R1.

In the next step S05, the control device 9 controls the upper chuck drivers 14A, 14B such that the substrate W is pressed with the pressing forces f1. The direction of the downward force, which the lower-surface brush 51 receives from the substrate W pressed with the pressing forces f1, is constant. Therefore, the lower-surface brush 51 uplifts the center portion of the substrate W. Thus, the center portion of the substrate W is gradually and upwardly moved from the reference position. Therefore, the portion in which the lower-surface brush 51 and the substrate W come into contact with each other is gradually decreased from the entire region R1 to become the annular region R3. At the point t3 in time at which the cleaning period ends, the center portion of the substrate W is moved to the position corresponding to the upper limit value.

In the next step S06, whether the cleaning period has ended is determined. The process waits until the cleaning period ends (NO in the step S06). If the cleaning period has ended (YES in the step S06), the process ends.

### 4. Effects

(1) The pair of upper holding devices 10A, 10B are controlled by the upper chuck drivers 14A, 14B such that the center portion of the substrate W is displaced in the upward direction or the downward direction in the period during which the lower-surface center region BC of the substrate W is cleaned by the lower-surface brush 51. Therefore, the substrate W can be deformed into the shape suitable for cleaning by the lower-surface brush 51. Therefore, a process of cleaning the substrate W can be made efficient.

(2) The upper chuck drivers 14A, 14B adjust the distance between the pair of upper holding devices 10A, 10B arranged to be opposite to each other with the substrate interposed therebetween, so that the substrate W can be easily deformed.

### Second Embodiment

FIG. 15 is an external perspective view showing the inner configuration of a substrate cleaning device in a second embodiment. With reference to FIG. 15, in the substrate cleaning device 1 in the second embodiment, the pair of upper holding devices 10A, 10B included in the substrate cleaning device 1 in the first embodiment shown in FIG. 2 are changed to a pair of upper holding devices 210A, 210B. Further, as for the functions of the substrate cleaning device 1 in the second embodiment, the upper chuck drivers 14A, 14B and the lower chuck drivers 13A, 13B included in the substrate cleaning device 1 in the first embodiment shown in FIG. 5 are changed to holding device drivers 221A, 221B and roller drivers 223A, 223B, respectively. Differences of the substrate cleaning device 1 in the second embodiment from the substrate cleaning device 1 in the first embodiment will be described below.

### 1. Pair of Upper Holding Devices

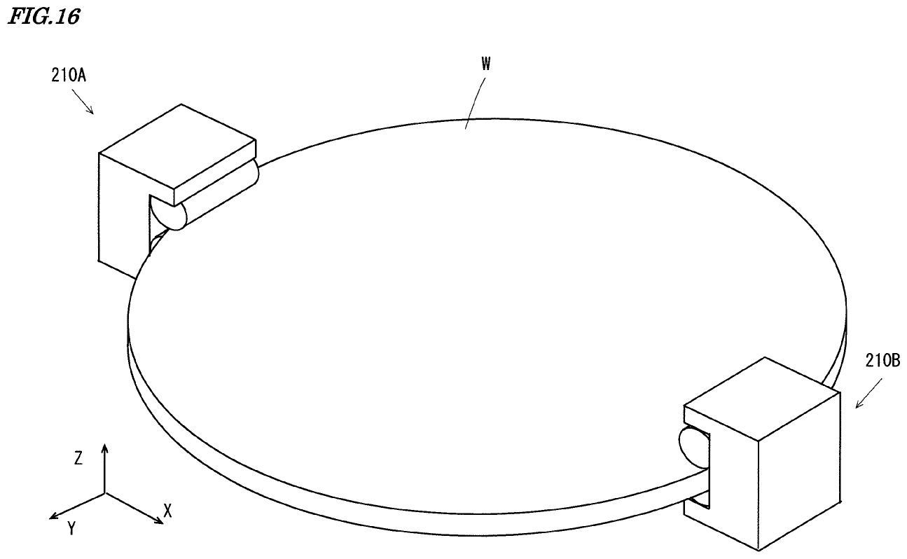

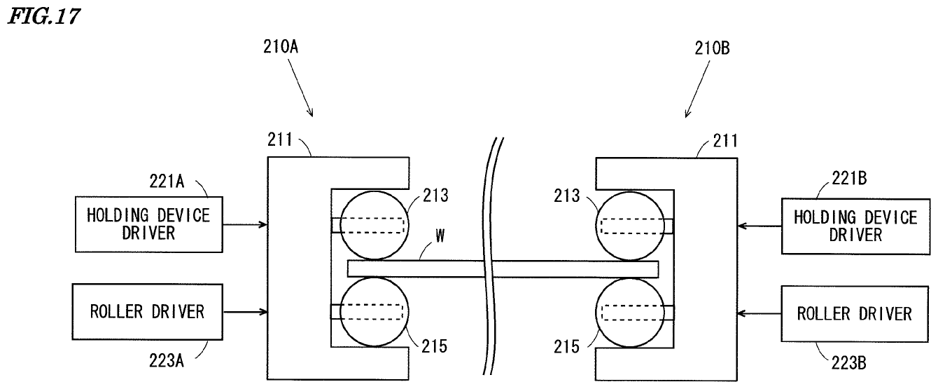

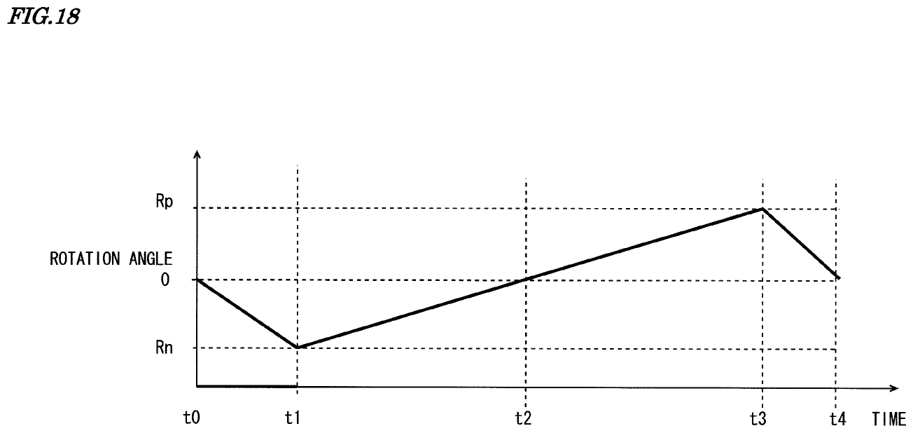

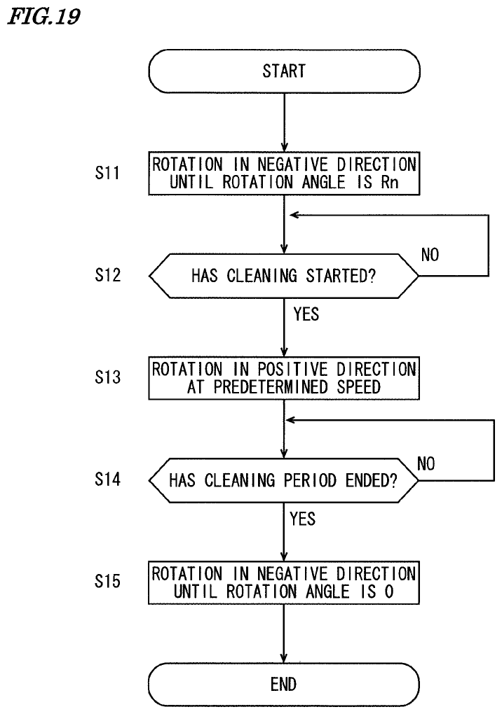

FIG. 16 is an external perspective view of the pair of upper holding devices in the second embodiment. FIG. 17 is a front view schematically showing the pair of upper holding devices in the second embodiment. With reference to FIGS. 16 and 17, the pair of upper holding devices 210A, 210B are arranged symmetrically with respect to the vertical plane extending in the Y direction (the forward-and-rearward direction) through the center of the suction holder 21 in plan view, and are provided to be movable in the X direction in a common horizontal plane. Each of the pair of upper holding devices 210A, 210B includes a roller supporter 211, an upper roller 213 and a lower roller 215. The upper roller 213 and the lower roller 215 have a columnar shape. Each of the upper roller 213 and the lower roller 215, with its rotation center as an axis, is rotatably supported by the roller supporter 211 such that its rotation shaft is parallel to the Y direction. The upper roller 213 is biased toward the lower roller 215. For example, the rotation shaft of the upper roller 213 is biased by an elastic body such as a spring in the downward direction. Therefore, the upper roller 213 and the lower roller 215 are in contact with each other with no gap therebetween when not holding the substrate W.

The holding device drivers 221A, 22B include air cylinders or motors as actuators. The holding device drivers 221A, 221B move the upper holding devices 210A, 210B such that the upper holding devices 210A, 210B are moved to be closer to each other or farther away from each other. Here, in a case in which the target positions of the upper holding devices 210A, 210B in the X direction are predetermined, the holding device drivers 221A, 221B can respectively adjust the positions of the upper holding devices 210A, 210B in the X direction based on the information about the target positions. For example, it is possible to insert the substrate W between the upper roller 213 and the lower roller 215 of each of the upper holding devices 210A, 210B by making the distance between the upper holding devices 210A, 210B be smaller than the outer diameter of the substrate W. In the period during which the holding device drivers 221A, 221B respectively adjust the positions of the upper holding devices 210A, 210B, the upper rollers 213 and the lower rollers 215 are freely rotatable such that the substrate W is smoothly inserted therebetween. In this stage, a plurality of portions of the outer peripheral end of the substrate W are respectively inserted between the upper roller 213 and the lower roller 215 of each of the upper holding devices 210A, 210B, whereby the outer peripheral end of the substrate W is held by the upper holding devices 210A, 210B, and the substrate W is firmly fixed.

At least one of the upper roller 213 and the lower roller 215 may be formed of a member having elasticity. In this case, it is not necessary to bias the rotation shaft of the upper roller 213 with an elastic body.

The roller drivers 223A, 223B include stepping motors and a plurality of gears. The plurality of gears transmit the rotational force of the stepping motor to each of the rotation shafts of the upper roller 213 and the lower roller 215. The plurality of gears are engaged with one another such that the upper roller 213 and the lower roller 215 are rotated in the opposite directions by the rotation of the stepping motor. Each of the roller drivers 223A, 223B rotates the upper roller 213 and the lower roller 215 in the opposite directions by driving the stepping motor. Each of the roller drivers 223A, 223B rotates the upper roller 213 and the lower roller 215 after the positions of the upper holding devices 210A, 210B are adjusted by the holding device drivers 221A, 221B.

The side surfaces of the upper roller 213 and the lower roller 215 that come into contact with the substrate W preferably have a predetermined friction coefficient such that a frictional force is generated in the portions that come into contact with the substrate W. In this case, idling of the upper roller 213 and the lower roller 215 with the substrate W being held can be prevented. Each of the roller drivers 223A, 223B rotates the upper roller 213 and the lower roller 215 in the opposite directions to displace the center portion of the substrate W. In a case in which each of the roller drivers 223A, 223B rotates the upper roller 213 in the direction in which the substrate W is to be sent out, and rotate the lower roller 215 in the direction in which the substrate W is to be drawn in, a force for causing the center portion of the substrate W to be displaced in the downward direction is exerted. Conversely, in a case in which each of the roller drivers 223A, 223B rotates the upper roller 213 in the direction in which the substrate W is to be drawn in and rotates the lower roller 215 in the direction in which the substrate W is to be sent out, a force for causing the center portion of the substrate W to be displaced in the upward direction is exerted. Hereinafter, the rotation direction of the upper roller 213 and the lower roller 215 with a force for causing the center portion of the substrate W to be displaced in the downward direction exerted is referred to as a negative direction, and the rotation direction of the upper roller 213 and the lower roller 215 with a force for causing the center portion of the substrate W to be displaced in the upward direction exerted is referred to as a positive direction.

### 2. Substrate Displacement Control

As described above, in the second embodiment, an uplift force to be applied to the lower-surface brush 51 is constant. When each of the roller drivers 223A, 223B rotates the upper roller 213 and the lower roller 215 in the negative direction, a force for pressing the lower-surface brush 51 in the downward direction is generated in the substrate W. When the force with which the substrate W presses the lower-surface brush 51 in the downward direction becomes larger than the uplift force, the lower-surface brush 51 is moved in the downward direction. When the force with which the substrate W presses the lower-surface brush 51 in the downward direction becomes equal to the uplift force during the movement of the lower-surface brush 51 in the downward direction, the lower-surface brush 51 is no longer moved in the downward direction and is stopped.

Further, when each of the roller drivers 223A, 223B rotates the upper roller 213 and the lower roller 215 in the positive direction, a force with which the substrate W presses the lower-surface brush 51 in the downward direction is reduced. When the force with which the substrate W presses the lower-surface brush 51 in the downward direction becomes smaller than the uplift force, the lower-surface brush 51 is moved in the upward direction. When the force with which the substrate W presses the lower-surface brush 51 in the downward direction becomes equal to the uplift force during the movement of the lower-surface brush 51 in the upward direction, the lower-surface brush 51 is no longer moved upwardly and is stopped.

The amount of displacement of the center portion of the substrate W is determined by the rotation angles of the upper roller 213 and the lower roller 215. Further, the force with which the substrate W presses the lower-surface brush 51 in the downward direction varies in the period during which the upper roller 213 and the lower roller 215 are rotated. In the period during which the rotation of the upper roller 213 and the lower roller 215 is stopped, the force with which the substrate W presses the lower-surface brush 51 in the downward direction is equal to the uplift force.

FIG. 18 is a first time chart showing one example of the change of the rotation angles of the upper roller and the lower roller. In the time chart of FIG. 18, the ordinate indicates the rotation angles of the upper roller 213 and the lower roller 215, and the abscissa indicates time. Further, the rotation angles of the upper roller 213 and the lower roller 215 with the value of the amount of displacement of the center portion of the substrate W being the upper limit value are Rp, and the rotation angles of the upper roller 213 and the lower roller 215 with the value of the amount of displacement of the center portion of the substrate W being the lower limit value are Rn.

With reference to FIG. 18, at a point to before cleaning of the substrate W by the lower-surface brush 51 is started, the rotation angles of the upper roller 213 and the lower roller 215 are 0. The point t1 in time is a point in time at which the cleaning of the lower-surface center region BC of the substrate W by the lower-surface brush 51 is started. From the point to to a time t1 in time, each of the roller drivers 223A, 223B rotates the upper roller 213 and the lower roller 215 in the negative direction until the rotation angle is Rn. During this time, because the upper roller 213 and the lower roller 215 are rotated in the negative direction, a force with which the substrate W presses the lower-surface brush 51 in the downward direction is generated, and the center portion of the substrate W is displaced downwardly together with the lower-surface brush 51. At the point t1 in time, the value of the amount of displacement of the center portion of the substrate W is the lower limit value.

Then, in the period from the point t1 to a point t3 in time, each of the roller drivers 223A, 223B rotates the upper roller 213 and the lower roller 215 in the positive direction until the rotation angles are Rp. The period from the point t1 to the point t3 in time is a cleaning period predetermined as a period during which the lower-surface center region BC of the substrate W is cleaned by the lower-surface brush 51. During this time, because the upper roller 213 and the lower roller 215 are rotated in the positive direction, the force with which the substrate W presses the lower-surface brush 51 in the downward direction is reduced to be smaller than the pressing forces, and the center portion of the substrate W is displaced upwardly together with the lower-surface brush 51. At the point t3 in time, the value of the amount of displacement of the center portion of the substrate W is the upper limit value.

In the period from the point t3 to a time t4 in time, each of the roller drivers 223A, 223B rotates the upper roller 213 and the lower roller 215 in the negative direction until the rotation angles are 0.

At the point t1 in time, the lower-surface brush 51 comes into contact with the substrate W in the center region R2 in the lower-surface center region BC of the substrate W. Therefore, at the point t1 in time, the lower-surface brush 51 comes into contact with the substrate W in the center region R2 in the lower-surface center region BC of the substrate W. Therefore, the center region R2 of the substrate W is cleaned.

At the point t2 in time at which the rotation angles of the upper roller 213 and the lower roller 215 are 0, the lower-surface brush 51 comes into contact with the substrate W in the entire region R1 in the lower-surface center region BC of the substrate W. Therefore, at the point t2 in time, the lower-surface brush 51 comes into contact with the substrate W in the entire region R1 in the lower-surface center region BC of the substrate W. Therefore, the entire region R1 (the lower-surface center region BC) of the substrate W is cleaned. In the period from the point t1 to the point t2 in time, the portion in which the lower-surface brush 51 and the substrate W come into contact with each other gradually spreads from the center region R2 to become the entire region R1.

At the point t3 in time, the lower-surface brush 51 comes into contact with the substrate W in the annular region R3 in the lower-surface center region BC of the substrate W. Therefore, at the point t3 in time, the lower-surface brush 51 comes into contact with the substrate W in the annular region R3 in the lower-surface center region BC of the substrate W. Therefore, the annular region R3 of the substrate W is cleaned. In the period from the point t2 to the point t3 in time, the portion in which the lower-surface brush 51 and the substrate W come into contact with each other is gradually decreased from the entire region R1 to become the annular region R3.

FIG. 19 is a flowchart showing one example of a flow of a substrate displacement control process. The substrate displacement control process is a process to be executed by the control device 9. With reference to FIG. 19, the control device 9 controls each of the roller drivers 223A, 223B to rotate the upper roller 213 and the lower roller 215 in the negative direction until the rotation angles are Rn (step S11). In the next step S12, whether cleaning by the lower-surface brush 51 has been started is determined. The process waits until the cleaning is started (NO in the step S12). If the cleaning has been started (YES in the step S12), the process proceeds to the step S13.

In the step S13, the control device 9 rotates the upper roller 213 and the lower roller 215 in the normal direction at a predetermined speed, and the process proceeds to the step S14. As shown in FIG. 18, the predetermined speed is a speed at which the rotation angles of the upper roller 213 and the lower roller 215 are changed from Rn to Rp in the cleaning period.

In the step S14, whether the cleaning period has ended is determined. The process waits until the cleaning period ends (NO in the step S14). If the cleaning period has ended (YES in the step S14), the process ends.

In the step S15, the control device 9 rotates the upper roller 213 and the lower roller 215 in the negative direction until the rotation angles are 0, and ends the process.

Although the upper roller 213 and the lower roller 215 are rotated in the positive direction at the predetermined speed from the point t1 to the point t3 in time by way of example in the present embodiment, the upper roller 213 and the lower roller 215 may be rotated in the negative direction at the predetermined speed from the point t1 to the point t3 in time after the upper roller 213 and the lower roller 215 are rotated until the rotation angles are Rp at the point t1 in time.

### 3. First Modified Example of Substrate Displacement Control

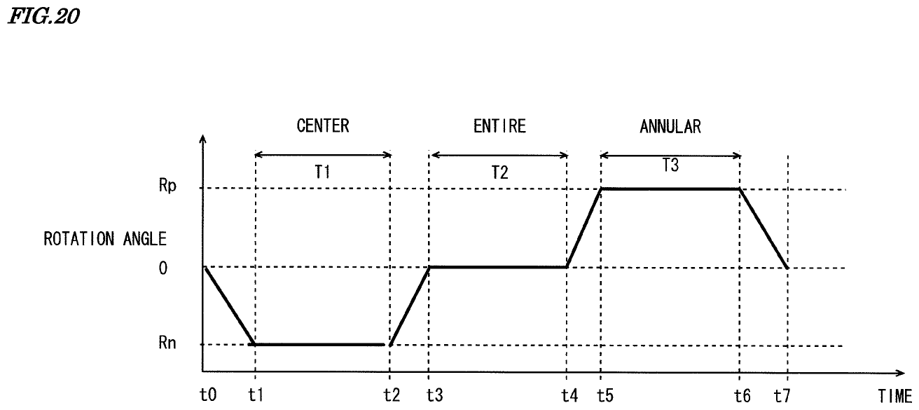

FIG. 20 is a first time chart showing one example of the change of the rotation angles of the upper roller and the lower roller in a first modified example. In the time chart of FIG. 20, the ordinate indicates the rotation angles of the upper roller 213 and the lower roller 215, and the abscissa indicates time. Further, the rotation angles of the upper roller 213 and the lower roller 215 with the value of the amount of displacement of the center portion of the substrate W being the upper limit value are Rp, and the rotation angles of the upper roller 213 and the lower roller 215 with the value of the amount of displacement of the center portion of the substrate W being the lower limit value are Rn.

With reference to FIG. 20, at a point to in time before the cleaning of the substrate W by the lower-surface brush 51 is started, the rotation angles of the upper roller 213 and the lower roller 215 are 0. A point t1 in time is a point in time at which the cleaning of the lower-surface center region BC of the substrate W by the lower-surface brush 51 is started. From the point to t0 a time t1 in time, each of the roller drivers 223A, 223B rotates the upper roller 213 and the lower roller 215 in the negative direction until the rotation angles are Rn. During this time, because the upper roller 213 and the lower roller 215 are rotated in the negative direction, a force with which the substrate W presses the lower-surface brush 51 in the downward direction is generated, and the center portion of the substrate W is displaced downwardly together with the lower-surface brush 51. At the point t1 in time, the value of the amount of displacement of the center portion of the substrate W is the lower limit value.

In a period T1 from the point t1 to a point t2 in time, the rotation angles Rn of the upper roller 213 and the lower roller 215 are maintained. The period T1 is a period predetermined as a period during which the center region R2 of the lower-surface center region of the substrate W is cleaned by the lower-surface brush 51. During this period, the lower-surface brush 51 comes into contact with the substrate W in the center region R2 in the lower-surface center region BC of the substrate W. Therefore, the center region R2 of the substrate W is cleaned in the period T1.

From the point t2 to a point t3 in time, each of the roller drivers 223A, 223B rotates the upper roller 213 and the lower roller 215 in the positive direction until the rotation angles are 0. During this time, because the upper roller 213 and the lower roller 215 are rotated in the positive direction, the force with which the substrate W presses the lower-surface brush 51 in the downward direction is reduced to be smaller than the pressing forces, and the center portion of the substrate W is displaced upwardly together with the lower-surface brush 51. At the point t3 in time, the center portion of the substrate W is located at the reference position.

Then, in a period T2 from the point t3 to a point t4 in time, the rotation angles θ of the upper roller 213 and the lower roller 215 are maintained. The period T2 is a period predetermined as a period during which the entire region R1 of the lower-surface center region BC of the substrate W is cleaned by the lower-surface brush 51. During this period, the lower-surface brush 51 comes into contact with the substrate W in the entire region R1 in the lower-surface center region BC of the substrate W. Therefore, the entire region R1 (the lower-surface center region BC) of the substrate W is cleaned in the period T2.

From the point t4 to a point t5 in time, each of the roller drivers 223A, 223B rotates the upper roller 213 and the lower roller 215 in the positive direction until the rotation angles are Rp. During this time, because the upper roller 213 and the lower roller 215 are rotated in the positive direction, the force with which the substrate W presses the lower-surface brush 51 in the downward direction is reduced to be smaller than the pressing forces, and the center portion of the substrate W is displaced upwardly together with the lower-surface brush 51. At the point t5 in time, the value of the amount of displacement of the center portion of the substrate W is the upper limit value.

Then, in a period T3 from the point t5 to a point t6 in time, the rotation angles Rp of the upper roller 213 and the lower roller 215 are maintained. The period T3 is a period predetermined as a period during which the annular region R3 of the lower-surface center region BC of the substrate W is cleaned by the lower-surface brush 51. During this time, the lower-surface brush 51 comes into contact with the substrate W in the annular region R3 in the lower-surface center region BC of the substrate W. Therefore, the annular region R3 of the substrate W is cleaned in the period T3.

In the period from the point t6 to a time t7 in time, each of the roller drivers 223A, 223B rotates the upper roller 213 and the lower roller 215 in the negative direction until the rotation angles are 0.

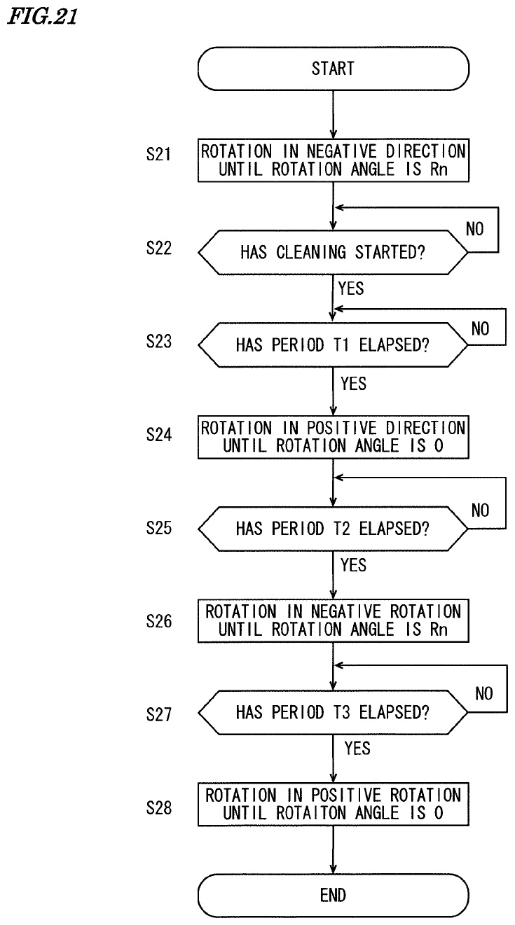

FIG. 21 is a flowchart showing one example of a flow of a substrate displacement control process in the first modified example. With reference to FIG. 21, the control device 9 controls each of the roller drivers 223A, 223B to rotate the upper roller 213 and the lower roller 215 in the negative direction until the rotation angles are Rn (step S21), and the process proceeds to the step S22.

In the step S22, whether the cleaning by the lower-surface brush 51 has been started is determined. The process waits until the cleaning is started (NO in the step S22). If the cleaning has been started (YES in the step S22), the process proceeds to the step S23.

In the step S23, whether the period T1 has elapsed is determined. The period T1 is a period predetermined as a period during which the center region R2 of the lower-surface center region BC of the substrate W is cleaned by the lower-surface brush 51. The process waits until the period T1 elapses (NO in the step S23). If the period T1 has elapsed (YES in the step S23), the process proceeds to the step S24.

In the step S24, the control device 9 controls each of the roller drivers 223A, 223B to rotate the upper roller 213 and the lower roller 215 in the positive direction until the rotation angles are 0, and the process proceeds to the step S25. In the step S25, whether the period T2 has elapsed is determined. The period T2 is a period predetermined as a period during which the entire region R1 of the lower-surface center region BC of the substrate W is cleaned by the lower-surface brush 51. The process waits until the period T2 elapses (NO in the step S25). If the period T2 has elapsed (YES in the step S25), the process proceeds to the step S26.

In the step S26, the control device 9 controls each of the roller drivers 223A, 223B to rotate the upper roller 213 and the lower roller in the positive direction until the rotation angles are Rp, and the process proceeds to the step S27. In the step S27, whether the period T3 has elapsed is determined. The period T3 is a period predetermined as a period during which the annular region R3 of the lower-surface center region BC of the substrate W is cleaned by the lower-surface brush 51. The process waits until the period T3 elapses (NO in the step S27). If the period T3 has elapsed (YES in the step S27), the process proceeds to the step S28. In the step S28, the control device 9 controls each of the roller drivers 223A, 223B to rotate the upper roller 213 and the lower roller in the negative direction until the rotation angles are 0, and the process ends.

### 4. Modified Examples of Substrate Displacement Control

The cycle of continuous rotation of the upper roller 213 and the lower roller 215 in the positive direction shown in FIG. 18 may be repeated. Further, the cycle of continuous rotation of the upper roller 213 and the lower roller 215 in the negative direction may be repeated. Further, the cycle of continuous rotation in the positive direction and the cycle of continuous rotation in the negative direction may be alternately repeated.

Further, the cycle of gradual rotation of the upper roller 213 and the lower roller 215 in the positive direction shown in FIG. 20 may be repeated. Further, the cycle of gradual rotation of the upper roller 213 and the lower roller 215 in the negative direction may be repeated. Further, the cycle of gradual rotation in the positive direction and the cycle of gradual rotation in the negative direction may be alternately repeated.

Further, the cycle of continuous rotation in the positive or negative direction and the cycle of gradual rotation in the positive or negative direction may be alternately repeated.

### 5. Modified Example of Pair of Upper Holding Devices

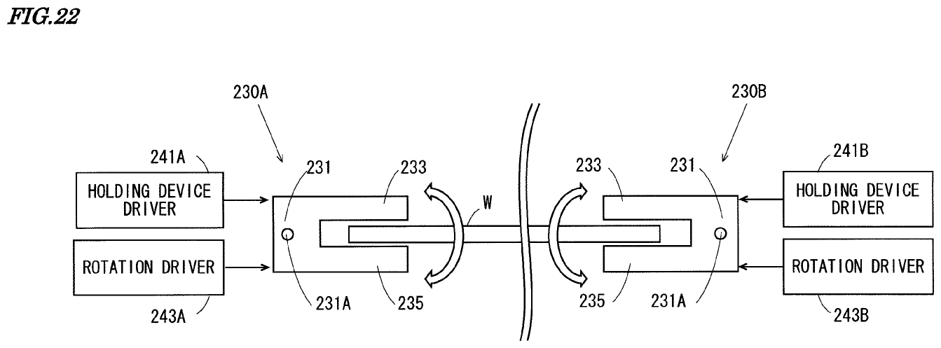

FIG. 22 is a front view schematically showing one example of a modified example of the pair of upper holding devices. With reference to FIG. 22, in the modified example of the second embodiment, the pair of upper holding devices 210A, 210B included in the substrate cleaning device 1 in the second embodiment are changed to a pair of upper holding devices 230A, 230B, and the holding device drivers 221A, 221B and the roller drivers 223A, 223B are respectively changed to holding device drivers 241A, 241B and rotation drivers 243A, 243B.

The pair of upper holding devices 230A, 230B are arranged symmetrically with respect to the vertical plane extending in the Y direction (the forward-and-rearward direction) through the center of the suction holder 21 in plan view, and are provided to be movable in the X direction in a common horizontal plane. Each of the pair of upper holding devices 230A, 230B includes a gripper 231, an upper-surface abutment portion 233 and a lower-surface abutment portion 235. The upper-surface abutment portion 233 and the lower-surface abutment portion 235 have a flat plate shape. The upper-surface abutment portion 233 and the lower-surface abutment portion 235 are supported by the gripper 231 such that the lower surface of the upper-surface abutment portion 233 faces the upper surface of the lower-surface abutment portion 235. The gripper 231 is rotatably supported at a rotation shaft 231A extending in parallel with the Y direction.

The upper-surface abutment portion 233 is supported by the gripper 231 so as to be movable in the upward-and-downward direction. The gripper 231 includes a mechanism that adjusts the distance between the upper-surface abutment portion 233 and the lower-surface abutment portion 235. Therefore, with the gripper 231 upwardly moving the upper-surface abutment portion 233, the substrate W is inserted into the space between the upper-surface abutment portion 233 and the lower-surface abutment portion 235. Thereafter, the gripper 231 downwardly moves the upper-surface abutment portion 233, so that the upper-surface abutment portion 233 and the lower-surface abutment portion 235 sandwich the substrate W. In this state, the upper-surface abutment portion 233 abuts against part of the upper surface of the substrate W, and the lower-surface abutment portion 235 abuts against part of the lower surface of the substrate W.

The holding device drivers 241A, 241 include air cylinders or motors as actuators. The holding device drivers 241A, 241B move the upper holding devices 230A, 230B such that the upper holding devices 210A, 210B are moved to be closer to each other or farther away from each other. Here, in a case in which the target positions of the upper holding devices 230A, 230B in the X direction are predetermined, the holding device drivers 241A, 241B can respectively adjust the positions of the upper holding devices 230A, 230B in the X direction based on the information about the target positions. For example, it is possible to insert the substrate W between the upper-surface abutment portion 233 and the lower-surface abutment portion 235 of each of the upper holding devices 230A, 230B by making the distance between the upper holding devices 230A, 230B be smaller than the outer diameter of the substrate W. In the period during which the holding device drivers 241A, 241B respectively adjust the positions of the upper holding devices 230A, 230B, the grippers 231 upwardly move the upper-surface abutment portions 233. In this stage, a plurality of portions of the outer peripheral end of the substrate W are inserted between the upper-surface abutment portion 233 and the lower-surface abutment portion 235 of each of the upper holding devices 230A, 230B. Thereafter, the grippers 231 downwardly move the upper-surface abutment portions 233, whereby the outer peripheral end of the substrate W is held by the upper holding devices 230A, 230B, and the substrate W is firmly fixed.

Each of the rotation drivers 243A, 243B includes a stepping motor. Each of the rotation drivers 243A, 243B drives the stepping motor to rotate the gripper 231 about the rotation shaft 231A. Each of the rotation drivers 243A, 243B rotates the gripper 231 after the positions of the upper holding devices 230A, 230B are adjusted by the holding device drivers 241A, 241B. In the period during which the holding device drivers 241A, 241B respectively adjust the positions of the upper holding devices 230A, 230B, each of the rotation drivers 243A, 243B fixes the gripper 231 at a position at which the abutment surface of each of the upper-surface abutment portion 233 and the lower-surface abutment portion 235 are horizontal such that the gripper 231 is not rotated.

The rotation drivers 243A, 243B rotate the gripper 231 of the upper holding device 230A and the gripper 231 of the upper holding device 230B in the opposite directions. In FIG. 22, in a case in which the rotation driver 243A rotates the gripper 231 of the upper holding device 230A clockwise, the rotation driver 243B rotates the gripper 231 of the upper holding device 230B counterclockwise. In FIG. 22, in a case in which the rotation driver 243A rotates the gripper 231 of the upper holding device 230A counterclockwise, the rotation driver 243B rotates the gripper 231 of the upper holding device 230B clockwise.

Hereinafter, the clockwise rotation of the gripper 231 of the upper holding device 230A by the upper holding device 230A and the counterclockwise rotation of the gripper 231 of the upper holding device 230B by the rotation driver 243B are referred to as the rotation of the pair of upper holding devices in a negative direction. Further, the counterclockwise rotation of the gripper 231 of the upper holding device 230A by the upper holding device 230A and the clockwise rotation of the gripper 231 of the upper holding device 230B by the upper holding device 230B are referred to as the rotation of the pair of upper holding devices in a forward direction.

In a case in which the pair of upper holding devices 230A, 230B cause the rotation of the pair of upper holding devices in the forward direction, a force that displaces the center portion of the substrate W in the upward direction is exerted. In a case in which the pair of upper holding devices 230A, 230B cause the rotation of the pair of upper holding devices in the negative direction, a force that displaces the center portion of the substrate W in the downward direction is exerted.

### 6. Effects

The substrate cleaning device 1 in the second embodiment has the similar effects as those of the substrate cleaning device 1 in the first embodiment. Further, in the upper roller 213 and the lower roller 215 of each of the pair of upper holding devices 210A, 210B, a force applied to the front surface of the substrate W by the upper roller 213 and the force applied to the back surface of the substrate W by the lower roller 215 are adjusted. Therefore, the substrate W can be easily deformed.

### Third Embodiment

Differences of a substrate cleaning device 1 in a third embodiment from the substrate cleaning device 1 in the second embodiment will be described below.

### 1. Configuration of Substrate Cleaning Device

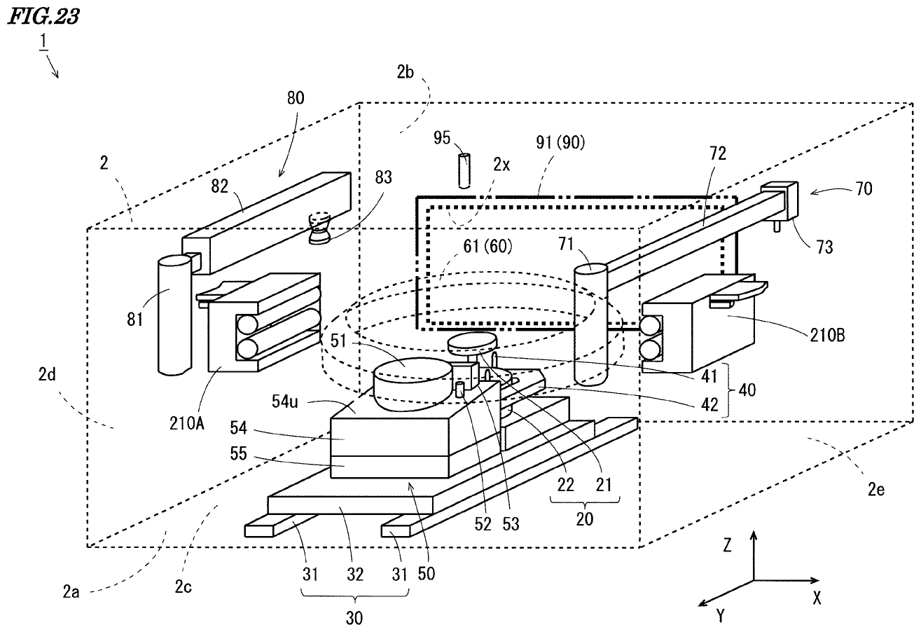

FIG. 23 is an external perspective view showing the inner configuration of the substrate cleaning device 1 in the third embodiment. With reference to FIG. 23, in regard to the

substrate cleaning device 1 in the third embodiment, a displacement sensor 95 is added to the substrate cleaning device 1 in the second embodiment shown in FIG. 15. The displacement sensor 95 is provided above the center portion of the substrate W held by the pair of upper holding devices 10A, 10B in the vertical direction. The displacement sensor 95 measures the distance to the center portion of the substrate W held by the pair of upper holding devices 10A, 10B. Therefore, the displacement sensor 95 detects the displacement of the center portion of the substrate W in the upward-and-downward direction (Z direction). Here, with a position at which the substrate W is held by the upper holding devices 10A, 10B as a reference position, the amount of displacement of the center portion of the substrate W is represented by the distance in the vertical direction between the position of the center portion of the substrate W and the reference position. The value of an amount of displacement is negative when the center portion of the substrate W is located at a position lower than the reference position, and is positive when the center portion of the substrate W is located at a position higher than the reference position.

In the substrate cleaning device 1 according to the third embodiment, the amount of displacement of the center portion of the substrate W varies based on the output of the displacement sensor 95. Specifically, the amount of displacement is adjusted such that the value of the amount of the displacement of the center portion of the substrate W falls between an upper limit value and a lower limit value. The upper limit value and the lower limit value for the amount of displacement of the center portion of the substrate W are predetermined values. As shown in FIG. 11, in a case in which the center portion of the substrate W is displaced and the value of the amount of displacement is positive, the substrate W has an upwardly protruding shape, and the lower-surface center region BC has a curved surface. The upper limit value is defined as a maximum value that allows the center portion of the substrate W to be displaced to a position higher than the reference position. As shown in FIG. 9, in a case in which the center of the substrate W is displaced to a position lower than the reference position and the value of the amount of displacement is negative, the substrate W has a downwardly protruding shape, and the lower-surface center region BC has a curved surface. The lower limit value is defined as a minimum value that allows the center portion of the substrate W to be displaced to a position lower than the reference position.

### 2. Substrate Displacement Control

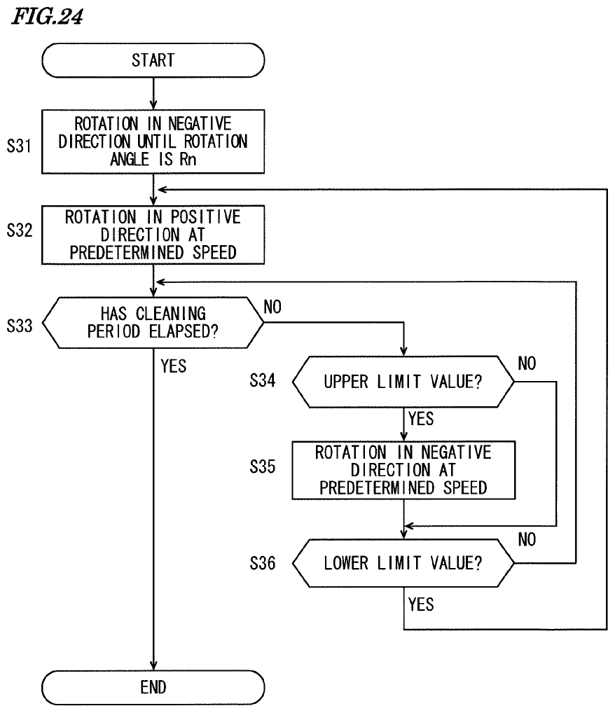

FIG. 24 is a flowchart showing one example of a flow of a substrate displacement control process in the third embodiment. With reference to FIG. 24, the control device 9 controls the roller drivers 223A, 223B to rotate the upper roller 213 and the lower roller 215 in the negative direction until the rotation angles are Rn (step S31), and the process proceeds to the step S32. In this stage, the lower-surface brush 51 comes into contact with the substrate W in the center region R2 in the lower-surface center region BC of the substrate W. Therefore, the center region R2 of the substrate W is cleaned by the lower-surface brush 51.

In the step S32, the control device 9 rotates the upper roller 213 and the lower roller 215 in the positive direction at a predetermined speed, and the process proceeds to the step S33. When the upper roller 213 and the lower roller 215 are rotated in the positive direction, the lower-surface brush 51 is lifted together with the substrate W. Therefore, the shape of the substrate W is changed, and the area of the contact surface in which the substrate W comes into contact with the lower-surface brush 51 is increased as the time elapses. Then, the entire region R1 of the substrate W is brought into contact with the lower-surface brush 51, and thereafter, the value of the amount of displacement of the center portion of the substrate W reaches the upper limit value.

In the step S33, whether a predetermined cleaning period, which is a period during which the lower-surface brush 51 cleans the substrate W, has elapsed is determined. If the cleaning period has not elapsed (NO in the step S33), the process proceeds to the step S34. If the cleaning period has elapsed (YES in the step S33), the process ends.

In the step S34, whether the value of the amount of displacement of the substrate W is the upper limit value is determined. The amount of displacement of the substrate W is detected based on the output of the displacement sensor 95. If the value of the amount of displacement of the substrate W is the upper limit value, the process proceeds to the step S35. If not, the process proceeds to the step S36. In a case in which the process proceeds to the step S35, the contact surface in which the lower-surface brush 51 and the substrate W come into contact with each other is the annular region R3 shown in FIGS. 11 and 12.

In the step S35, the control device 9 rotates the upper roller 213 and the lower roller 215 in the negative direction at a predetermined speed, and the process proceeds to the step S36. When the upper roller 213 and the lower roller 215 are rotated in the negative direction, the lower-surface brush 51 is lowered together with the substrate W. Therefore, the shape of the substrate W is changed, and the area of the contact surface in which the substrate W comes into contact with the lower-surface brush 51 is gradually reduced. Then, the center region R2 of the substrate W is brought into contact with the lower-surface brush 51, and thereafter, the value of the amount of displacement of the center portion of the substrate W reaches the lower limit value.

In the step S36, whether the value of the amount of displacement of the substrate W is the lower limit value is determined. The amount of displacement of the substrate W is detected based on the output of the displacement sensor 95. If the value of the amount of displacement of the substrate W is the lower limit value, the process returns to the step S33. If not, the process returns to the step S32.

### 3. Effects

The substrate cleaning device 1 in the third embodiment has similar effects as those of the substrate cleaning devices 1 in the first and second embodiments. Further, the pair of upper holding devices 10A, 10B are controlled such that the displacement of the substrate W detected by the displacement sensor 95 falls within a predetermined range. Therefore, the substrate W can be displaced to have the shape suited for the cleaning process performed by the lower-surface brush 51. Further, even when the pressing forces to be applied to the lower-surface brush 51 are changed, the substrate W can be cleaned without being damaged.

### Other Embodiments

(1) The substrate displacement control process in the third embodiment can also be applied to the substrate cleaning device 1 in the first embodiment. In this case, the upper limit value is the value of the amount of displacement of the substrate W with the center portion of the substrate W being located at the reference position, and the lower limit value is the value of the minimum amount of displacement of the substrate W that allows the center portion of the substrate W to be displaced to a position lower than the reference position. Therefore, the center region R2 and the entire region R1 can be cleaned in order by the lower-surface brush 51.

(2) In the present embodiment, a force to be applied to the substrate W by the pair of upper holding devices 10A, 10B (210A, 210B, 230A, 230B) is changed, so that a force to be applied to between the substrate W and the lower-surface brush 51 is changed. The present invention is not limited to this. A force to be exerted between the substrate W and the lower-surface brush 51 may be changed by keeping of the force to be applied to the substrate W by the pair of upper holding devices 10A, 10B (210A, 210B, 230A, 230B) constant and a change in pressing force for uplifting the lower-surface brush 51.

(3) While the process of cleaning the lower-surface center region BD of the substrate W with use of the lower-surface brush 51 is described by way of example in the second and third embodiments, the present invention is not limited to this. The substrate cleaning device in the second and third embodiments may deform the substrate W when the upper surface of the substrate W is cleaned or dried.

In this case, in a case in which the upper surface of the substrate W is cleaned or dried, the substrate W is deformed such that the value of the amount of displacement of the substrate W is the upper limit value or the lower limit value. For example, in a case in which the substrate W is cleaned while the substrate is deformed such that the value of the amount of displacement of the substrate W is the upper limit value, the cleaning liquid flows toward the periphery of the substrate W. Therefore, it is possible to efficiently clean the peripheral portion of the substrate W by supplying the cleaning liquid to the center portion. Further, in a case in which the substrate W is dried while being deformed such that the value of the amount of displacement of the substrate W is the upper limit value, it is possible to cause the liquid on the substrate W to flow to the periphery and efficiently dry the substrate W by blowing air for drying to the center portion of the substrate W.

### Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained. As each of various elements recited in the claims, various other elements having configurations or functions described in the claims can be also used.

In the above-mentioned embodiment, the pair of upper holding devices 10A, 10B (210A, 210B, 230A, 230B) are examples of a substrate holder, the lower-surface brush 51 is an example of a processor, the control device 9 is an example of a holding controller, and the upper chucks 12A, 12B are an example of two pressers. The upper roller 213 and the upper-surface abutment portion 233 are examples of an upper gripper, and the lower roller 215 and the lower-surface abutment portion 235 are examples of a lower gripper. The lower-surface brush 51 is an example of a cleaner, and the displacement sensor 95 is an example of a displacement sensor.

1. A substrate processing apparatus comprising:
a substrate holder that holds an outer peripheral end of a substrate;
a processor that processes a front surface or a back surface of the substrate; and
a holding controller that controls the substrate holder such that a center portion of the substrate is displaced in an upward direction or a downward direction in a period during which the substrate is processed by the processor.

2. The substrate processing apparatus according to claim 1, wherein
the substrate holder has two pressers that are arranged to be opposite to each other with the substrate interposed between the two pressers, and
the holding controller adjusts a distance between the two pressers.

3. The substrate processing apparatus according to claim 1, wherein
the substrate holder has two grippers that are arranged to be opposite to each other with the substrate interposed between the two grippers,
each of the two grippers includes an upper gripper that abuts against the front surface of the substrate and a lower gripper that abuts against the back surface of the substrate, and
the holding controller adjusts a force to be applied to the front surface of the substrate by the upper gripper and a force to be applied to the back surface of the substrate by the lower gripper.

4. The substrate processing apparatus according to claim 1, wherein
the processor includes a cleaner that comes into contact with a lower surface of the substrate to clean the lower surface of the substrate, and
the holding controller controls the substrate holder such that the center portion of the substrate is displaced in the upward direction or the downward direction in a period during which the cleaner cleans a lower-surface center portion of the substrate.

5. The substrate processing apparatus according to claim 1, further comprising a displacement sensor that detects displacement of the substrate, wherein the holding controller controls the substrate holder such that displacement of the substrate falls within a predetermined range.

6. A substrate processing apparatus, comprising:
a substrate holder that holds an outer peripheral end of a substrate;
a displacement sensor that detects displacement of a center portion of the substrate; and
a holding controller that controls the substrate holder such that the center portion of the substrate is displaced in an upward direction or a downward direction, wherein
the holding controller, based on displacement detected by the displacement sensor, displaces the center portion of the substrate in the upward direction or the downward direction such that displacement of the center portion of the substrate held by the substrate holder falls within a predetermined range.

7. A substrate processing method that is to be performed in a substrate processing apparatus, the substrate processing apparatus comprising:
a substrate holder that holds an outer peripheral end of a substrate; and
a processor that processes a front surface or a back surface of the substrate, and
the substrate processing method including a holding control step of controlling the substrate holder such that a center portion of the substrate is displaced in an upward direction or a downward direction in a period during which the substrate is processed by the processor.

8. A substrate processing method that is to be performed in a substrate processing apparatus, the substrate processing apparatus comprising:
a substrate holder that holds an outer peripheral end of a substrate; and
a displacement sensor that detects displacement of a center portion of the substrate; and
a holding controller that controls the substrate holder such that the center portion of the substrate is displaced in an upward direction or a downward direction, and
the substrate processing method including controlling the substrate holder, based on displacement detected by the displacement sensor, to displace the center portion of the substrate in the upward direction or the downward direction such that displacement of the center portion of the substrate held by the substrate holder falls within a predetermined range.
